(19) United States
(12) Patent Application Publication
(10) Pub. No.: US 2012/0286344 A1
(43) Pub. Date: Nov. 15, 2012

(54) NON-VOLATILE MEMORY DEVICES AND METHODS OF FORMING THE SAME

(76) Inventor: Changhyun LEE, Suwon-si (KR)

(21) Appl. No.: 13/468,649

(22) Filed: May 10, 2012

(30) Foreign Application Priority Data
May 12, 2011 (KR) 10-2011-0044787
Sep. 19, 2011 (KR) 10-2011-0094240

(51) Int. Cl. H01L 29/78

(52) U.S. Cl. 257/314; 257/E29.255

(57) ABSTRACT

A non-volatile may include a plurality of device isolation patterns disposed in a substrate to define an active region extending in a first direction, a gate pattern disposed on the substrate to extend in a second direction crossing the first direction, a charge storing pattern disposed between the active region and the gate pattern, a blocking dielectric layer disposed between the charge storing pattern and the gate pattern, and a tunnel dielectric layer disposed between the active region and the charge storing pattern. A center area of a top surface of the active region includes one of a rounded surface or a tip, and the center area of the top surface of the active region corresponds to an uppermost portion of the active region and the uppermost portion of the active region is disposed at a level lower than a lowermost portion of the gate pattern.

### CROSS-REFERENCE TO RELATED APPLICATIONS

This U.S. non-provisional patent application claims priority under 35 U.S.C. §119 to Korean Patent Application Nos. 10-2011-0044787 and 10-2011-0094240, filed on May 12, 2011 and Sep. 19, 2011, respectively, the disclosure of which is incorporated by reference herein in their entireties.

### BACKGROUND

The inventive concept relates to non-volatile memory devices and methods of forming the same and, more particularly, to non-volatile memory devices including charge storing patterns and methods of forming the same.

Semiconductor memory devices may classified into, for example, volatile memory devices and non-volatile memory devices. The volatile memory devices may lose their stored data when their power supplies are interrupted. A dynamic random access memory (DRAM) device and a static random access memory (SRAM) device may be typical volatile memory devices. The non-volatile memory devices may retain their stored data even though their power supplies are interrupted. Due to the non-volatile characteristic, the non-volatile memory devices may be used as storage mediums installed in electronic products and/or mobile products.

The improvement of various characteristics of the non-volatile memory devices may be required as a result of the development of the semiconductor industry. For example, data stored in the non-volatile memory devices may be lost by external causes and/or internal causes. The loss of the data of the non-volatile memory devices may be one of main errors. Recently, various research is being conducted for improving various characteristics of the non-volatile memory devices in response to the high development of the semiconductor industry.

### SUMMARY

Embodiments of the inventive concept may provide non-volatile memory devices with increased reliability.

Embodiments of the inventive concept may provide methods of forming a non-volatile memory device with increased reliability.

In accordance with an exemplary embodiment of the present invention, a non-volatile memory device is provided. The non-volatile memory device may include: a plurality of device isolation patterns disposed in a substrate to define an active region extending in a first direction, a gate pattern disposed on the substrate to extend in a second direction crossing the first direction, a charge storing pattern disposed between the active region and the gate pattern, a blocking dielectric layer disposed between the charge storing pattern and the gate pattern and a tunnel dielectric layer disposed between the active region and the charge storing pattern. A center area of a top surface of the active region may include one of a rounded surface or a tip. The center area of the top surface of the active region may correspond to the uppermost portion of the active region and the uppermost portion of the active region may be disposed at a level lower than the lowermost portion of the gate pattern.

In an embodiment, an intensity of an electric field provided to the center area of the top surface of the active region may be greater than an intensity of an electric field provided to an edge area of the top surface of the active region when an operation voltage is applied to the gate pattern.

In an embodiment, the lowermost portion of the gate pattern may be disposed at a level higher than the uppermost portion of the charge storing pattern.

In an embodiment, the entire top surface of the active region may be rounded.

In an embodiment, the top surface of the active region may have a first radius in a direction parallel to a top surface of the substrate and a second radius in a direction vertical to the top surface of the substrate, and the first radius may be less than the second radius.

In an embodiment, the top surface of the active region may further include a first surface connecting the center area of the top surface of the active region to a sidewall of the active region, and an angle between the sidewall and the first surface may be equal to or greater than about 90 degrees and less than about 180 degrees.

In an embodiment, the entire center area of the top surface of the active region may be rounded, and the rounded center area of the top surface may have a radius curvature less than a half of a width of the active region in the second direction.

In an embodiment, a connection surface of the sidewall and the first surface may be rounded, and the rounded connection surface may have a radius curvature less than a half of a width of the active region in the second direction.

In an embodiment, the center area of the top surface of the active region further may include a second surface parallel to a top surface of the substrate and a connection surface connecting the first surface to the second surface. The connection surface of the first and second surfaces may be rounded, and the rounded connection surface may have a radius curvature less than a half of a width of the active region in the second direction.

In an embodiment, the tip of the top surface of the active region may have a radius curvature less than about 30 percent of a width of the active region in the second direction.

In an embodiment, the top surface of the active region may include a pair of first surfaces extending in parallel to a top surface of the substrate from a pair of sidewalls of the active region toward the center area of the top surface of the active region. The center area of the top surface of the active region may be protruded above the pair of first surfaces to be rounded. A maximum width in second direction of the center area of the top surface of the active region may be less than a minimum width between the pair of sidewalls of the active region.

In an embodiment, a top surface of the device isolation pattern may be disposed at a level lower than the uppermost portion of the active region.

In an embodiment, a top surface of the device isolation pattern may be disposed at a level equal to or higher than the uppermost portion of the active region.

In an embodiment, the device isolation pattern may include a first dielectric pattern and a second dielectric pattern, and the first dielectric pattern and the second dielectric pattern may include dielectric materials different from each other, respectively.

In an embodiment, the non-volatile memory device may further include: an air gap disposed in the device isolation pattern. A top end of the air gap may be disposed at a level lower than the uppermost portion of the active region. The tunnel dielectric layer, the charge storing pattern and the blocking dielectric layer may extend on the device isolation pattern and the air gap.

In an embodiment, the air gap may be in a closed state by the device isolation pattern or the tunnel dielectric layer.

In an embodiment, a vertical distance from a top surface of the device isolation pattern to the top end of the air gap may become greater toward the active region.

In accordance with an exemplary embodiment of the present invention, a non-volatile memory device is provided. The non-volatile memory device may include: device isolation patterns disposed in a substrate to define an active region extending in a first direction, a gate pattern disposed on the substrate to extend in a second direction crossing the first direction, a charge storing pattern disposed between the active region and the gate pattern, a blocking dielectric layer disposed between the charge storing pattern and the gate pattern and a tunnel dielectric layer disposed between the active region and the charge storing pattern. A center area of a top surface of the active region corresponds to an uppermost portion of the active region. Moreover, the center area of the top surface of the active region includes an electric field focusing region and a portion of the active region disposed under the electric field focusing region, and the lowermost portion of the gate pattern is disposed at a level higher than the electric field focusing region of the active region. In addition, an uppermost portion of the charge storing pattern is disposed at a level lower than the lowermost portion of the gate pattern.

In an embodiment, the edge area of the top surface of the active region may be inclined; the edge area may connect the center area of the top surface of the active region to a sidewall of the active region and an angle between the edge area and the sidewall may be equal to or greater than about 90 degrees and less than about 180 degrees.

In an embodiment, the active region may include a first portion and a second portion disposed on the first portion. A width of the second portion in the second direction may be less than a width of the first portion in the second direction.
In accordance with an exemplary embodiment of the inventive concept, a method for forming a non-volatile memory device is provided. The method may include forming a plurality of mask patterns on a substrate and the mask patterns have line shapes extending in a first direction, forming a plurality of trenches in the substrate by etching exposed portions of the substrate using the mask patterns as etch masks, thereby defining a plurality of preliminary active regions in the substrate which are surrounded by the trenches, removing the mask patterns, forming a device isolation pattern in a respective one of each of the trenches, performing one of a thermal treatment process or an etching process on the preliminary active regions to transform the preliminary active regions into a plurality of active regions, and forming a tunnel dielectric layer conformally on substantially the entire substrate, substantially the entire device isolation patterns and substantially the entire active regions.

The method further includes forming a charge storing pattern conformally on the tunnel dielectric layer, forming a blocking dielectric layer conformally on the charge storing pattern and forming a gate pattern conformally on the blocking dielectric layer. A center area of a top surface of the active regions corresponds to an uppermost portion of the active regions and includes an electric field focusing region and a portion of the active regions disposed under the electric field focusing region, at least a part of the center area of the top surface of the active regions is rounded, a lowermost portion of the gate pattern is disposed at a level higher than the electric field focusing region of the active regions, and an uppermost portion of the charge storing pattern is disposed at a level lower than the lowermost portion of the gate pattern.

### BRIEF DESCRIPTION OF THE DRAWINGS

Exemplary embodiments of the inventive concept can be understood in more detail in view of the attached drawings and accompanying detailed description.

FIG. 1 is a plan view illustrating a non-volatile memory device according to an exemplary embodiment of the inventive concept;

FIG. 2 is a cross-sectional view taken along a line I-I′ of FIG. 1 to illustrate a non-volatile memory device according to an exemplary embodiment of the inventive concept;

FIGS. 3A to 3C are enlarged views illustrating a portion ‘A’ of FIG. 2;

FIGS. 4A to 4G are cross-sectional views illustrating modified examples of a device isolation pattern in a non-volatile memory device according to an exemplary embodiment of the inventive concept;

FIGS. 5A to 5D are cross-sectional views illustrating a method of forming a non-volatile memory device according to an exemplary embodiment of the inventive concept;

FIGS. 6A and 6B are cross-sectional views illustrating an modified example of a method of forming a non-volatile memory device according to an exemplary embodiment of the inventive concept;

FIGS. 7A to 7C are cross-sectional views illustrating a modified example of a method of forming a non-volatile memory device according to an exemplary embodiment of the inventive concept;

FIGS. 8A to 8C are cross-sectional views illustrating a modified example of a method of forming a non-volatile memory device according to an exemplary embodiment of the inventive concept;

FIGS. 9A and 9B are cross-sectional views illustrating a modified example of a method of forming a non-volatile memory device according to an exemplary embodiment of the inventive concept;

FIG. 10 is a cross-sectional view illustrating a non-volatile memory device according to an exemplary embodiment of the inventive concept;

FIGS. 11A and 11B are enlarged views illustrating a portion ‘B’ of FIG. 10;

FIGS. 12A to 12C are cross-sectional views illustrating a method of forming a non-volatile memory device according to an exemplary embodiment of the inventive concept;

FIG. 13 is a cross-sectional view illustrating a non-volatile memory device according to an exemplary embodiment of the inventive concept;

FIGS. 14A to 14C are cross-sectional views illustrating a method of forming a non-volatile memory device according to an exemplary embodiment of the inventive concept;

FIG. 15 is a schematic block diagram illustrating an example of electronic systems including non-volatile memory devices according to an exemplary embodiment of the inventive concept; and

FIG. 16 is schematic block diagram illustrating an example of memory cards including non-volatile memory devices according to an exemplary embodiment of the inventive concept.

### DETAILED DESCRIPTION OF EXEMPLARY EMBODIMENTS

Exemplary embodiments of inventive concept will now be described more fully hereinafter with reference to the accompanying drawings, in which exemplary embodiments of the inventive concept are shown. It should be noted, however, that exemplary embodiments of the inventive concept are not limited to the following exemplary embodiments, and may be implemented in various forms. In the drawings, embodiments of the inventive concept are not limited to the specific examples provided herein and are exaggerated for clarity.

The terminology used herein is for the purpose of describing particular embodiments only and is not intended to limit exemplary embodiments of the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present.

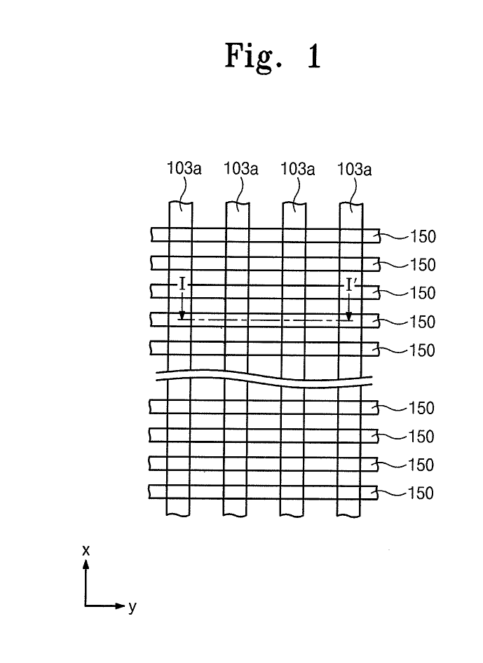

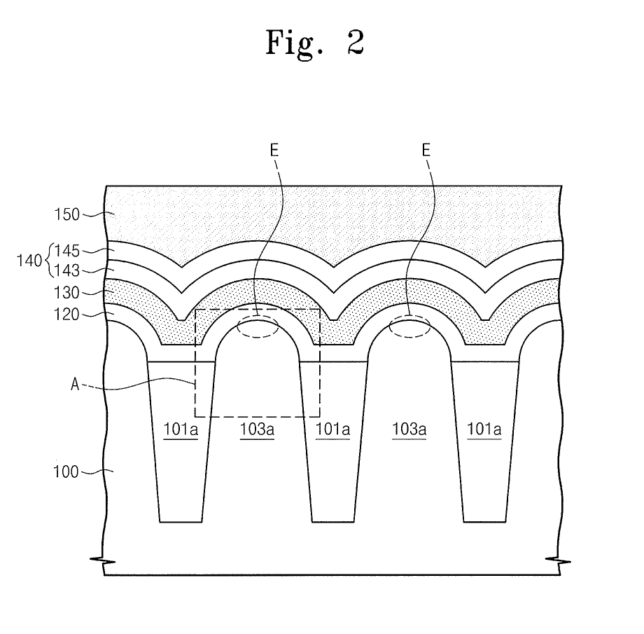

Hereinafter, a non-volatile memory device according to an exemplary embodiment of the inventive concept will be described with reference to drawings. FIG. 1 is a plan view illustrating a non-volatile memory device according to an exemplary embodiment of the inventive concept, and FIG. 2 is a cross-sectional view taken along a line I-I′ of FIG. 1.

Referring to FIGS. 1 and 2, device isolation patterns 101a may be disposed in a substrate 100 to define active regions 103a. The active region 103a may have, for example, a line shape extending in a first direction. The first direction may be, for example, parallel to an x-axis. In an embodiment, the active region 103a may be, for example, a portion of the substrate 100 surrounded by the device isolation patterns 101a. The substrate 100 may include, for example, a semiconductor material. For example, the substrate 100 may include at least one of silicon and germanium.

According to the present embodiment, an entire top surface of the active region 103a may have, for example, a round shape having a predetermined radius curvature. The top surface of the active region 103a may be, for example, arch-shaped. In an embodiment, the radius curvature of the top surface of the active region 103a may be, for example, greater than about 0 nm and equal to or less than about 10 nm.

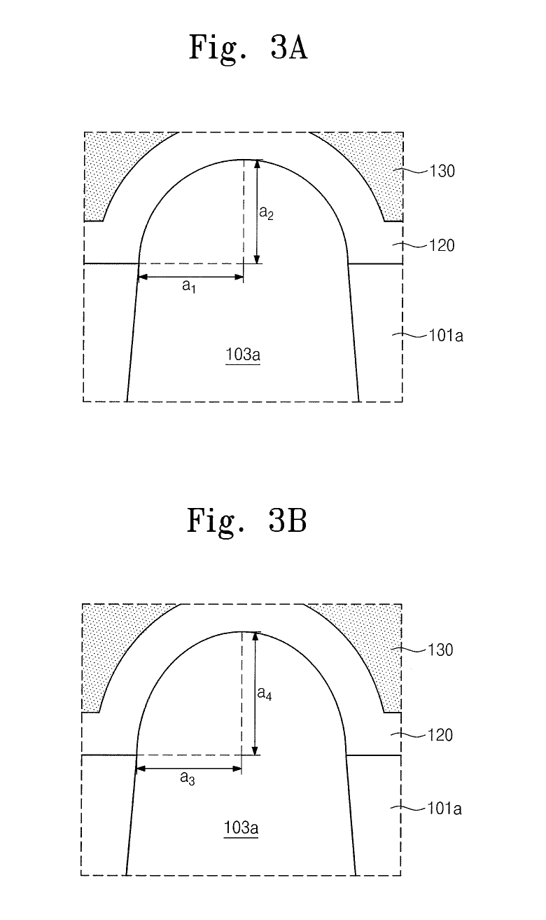

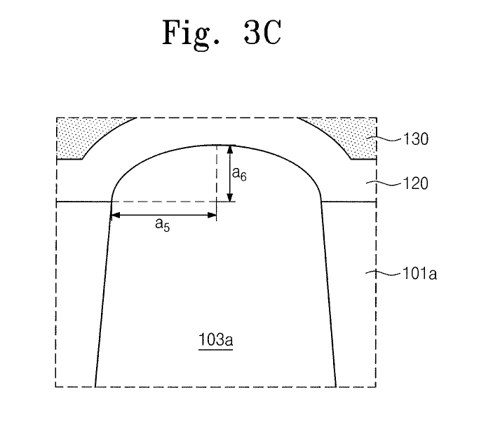

The top surface of the active region 103a may have various round shapes. Hereinafter, the top surface of the active region 103a will be described in more detail with reference to drawings. FIGS. 3A to 3C are enlarged views illustrating a portion ‘A’ of FIG. 2 to explain various examples of the top surface of the active region 103a.

Referring to FIG. 3A, the top surface of the active region 103a may have, for example, a half circle shape. In other words, for example, the top surface of the active region 103a may have a first radius a1 in a direction parallel to a top surface of the substrate 100 and a second radius a2 in a direction vertical to the top surface of the substrate 100, and the first radius a1 may be equal to the second radius a2.

Alternatively, as illustrated in FIGS. 3B and 3C, the top surface of the active region 103a may have, for example, a half ellipse shape. As illustrated in FIG. 3B, the top surface of the active region 103a may have, for example, a third radius a3 in the direction parallel to the top surface of the substrate 100 and a fourth radius a4 in the direction vertical to the top surface of the substrate 100, and the third radius a3 may be less than the fourth radius a4. That is, the top surface of the active region 103a may have the half ellipse shape with a short axis being the third radius a3 and a long axis being the fourth radius a4.

Or, as illustrated in FIG. 3C, the top surface of the active region 103a may have, for example, a fifth radius a5 in the direction parallel to the top surface of the substrate 100 and a sixth radius a6 in the direction vertical to the top surface of the substrate 100, and the fifth radius a5 may be greater than the sixth radius a6. The top surface of the active region 103a may have the half ellipse shape with a short axis being the sixth radius a6 and a long axis being the fifth radius a5.

However, exemplary embodiments of the inventive concept are not limited to the above examples. The top surface of the active region 103a may take the rounded surfaces of various shapes.

The top surface of the active region 103a may include, for example, a center area and an edge area. The center area of the top surface of the active region 103a may be the uppermost portion of the active region 103a. The center area of the top surface of the active region 103a may be an electric field focusing region E. A center portion of the active region 103a may include the electric field focusing region E and a portion of the active region 103a disposed under the electric field focusing region E. The portion of the active region 103a except the center portion may be an edge portion of the active region 103a.

In an embodiment, the uppermost portion of the active region 103a may be disposed, for example, at a level higher than a top surface of the device isolation pattern 101a. Thus, the active region 103a may protrude above the device isolation pattern 101a. The device isolation pattern 101a may include, for example, a dielectric material. For example, the device isolation pattern 101a may include silicon oxide, silicon nitride, and/or silicon oxynitride.

A gate pattern 150 may be disposed on the substrate 100 to extend in a second direction. The second direction may cross the first direction. In an embodiment, the second direction may be, for example, perpendicular to the first direction. For example, the second direction may be parallel to a y-axis.

Lowermost portions of the gate pattern 150 may be disposed, for example, at a level higher than the uppermost portion of the active region 103a. In other words, the lowermost portions of the gate pattern 150 may be disposed at a level higher than the electric field focusing region E of the active region 103a.

In the present embodiment, when an operation voltage is applied to the gate pattern 150, an electric field may focus on the electric field focusing region E. As a result, the intensity of the electric field provided to the electric field focusing region E may be greater than the intensity of the electric field provided to the edge area of the top surface of the active region 103a.

The gate pattern 150 may include a conductive material. For example, the gate pattern 150 may include at least one of a doped semiconductor (e.g., a doped poly-silicon or a doped silicon-germanium, etc), metal (e.g, tantalum (Ta), tungsten (W), titanium (Ti), or aluminum (Al), etc), a metal-semiconductor compound (e.g., tungsten silicide, titanium silicide, a cobalt silicide, or a tantalum silicide, etc), and a conductive metal nitride (e.g., tungsten nitride (WN), titanium nitride (TiN), tantalum nitride (TaN), or titanium-aluminum nitride (TiAlN), etc).

A charge storing pattern 130 may be disposed between the active region 103a and the gate pattern 150. The charge storing pattern 130 may cover the entire surface of the substrate 100. In other words, a plurality of the gate patterns 150 may be disposed on one charge storing pattern 130. Alternatively, the charge storing pattern 130 may be provided in plural. In this case, the charge storing patterns 130 may be, for example, line shapes extending in the second direction. In other words, the plurality of the charge storing patterns 130 may extend parallel to each other, and each of the charge storing patterns 130 may be disposed under each of the gate patterns 150. However, exemplary embodiments of the inventive concept are not limited to the above shapes of the charge storing pattern 130. The charge storing pattern 130 may have various shapes.

In an embodiment, the charge storing pattern 130 may have, for example, a shape formed along a profile of the active region 103a and the device isolation pattern 101a.

In an embodiment, the uppermost portion of the charge storing pattern 130 may be disposed at, for example, a level lower than the lowermost portion of the gate pattern 150.

The charge storing pattern 130 may include charge trapping sites capable of storing charges. For example, the charge storing pattern 130 may include at least one of silicon nitride, an insulating metal oxide (e.g., hafnium oxide or aluminum oxide, etc), metal-silicon oxide, and nano dots. For example, the charge storing pattern 130 may include at least one of dots formed of nano crystalline silicon, dots formed of nano crystalline silicon-germanium, and dots formed of nano crystalline metal. The dots included in the charge storing pattern 130 may be insulated from each other by at least one of oxide, nitride, oxynitride, and high-k dielectric. The charge storing pattern 130 may also be formed of any combination of the materials described above.

According to the present embodiment, since the intensity of the electric field in the electric field focusing region E of the active region 103a is greater than the intensity of the electric field in the edge area of the top surface of the active region 103a, charges may be stored in the charge storing pattern 130 disposed on the electric field focusing region E of the active region 103a. In other words, it is possible to minimize the amount of the charges stored in the charge storing pattern 130 disposed on the edge area of the top surface of the active region 103a. Additionally, since the intensity of the electric field in the edge area of the surface of the active region 103a is relatively less, it is possible to minimize the phenomenon that the charges stored in the charge storing pattern 130 on the electric field focusing region E of one active region 103a are spread into the charge storing pattern 130 on a neighboring active region 103a.

A tunnel dielectric layer 120 may be disposed between the active region 103a and the charge storing pattern 130. The tunnel dielectric layer 120 may be single-layered or multi-layered. The tunnel dielectric layer 120 may include, for example, at least one of oxide, nitride, metal oxide, and oxynitride. The tunnel dielectric layer 120 may cover an entire surface of the active region 103a. In an embodiment, the tunnel dielectric layer 120 on the active region 103a may extend to be disposed on the device isolation pattern 101a.

A blocking dielectric layer 140 may be disposed between the charge storing pattern 130 and the gate pattern 150. The blocking dielectric layer 140 may include, for example, a barrier dielectric layer 143 and a high-k dielectric layer 145. The high-k dielectric layer 145 may include, for example, a dielectric material having a dielectric constant higher than that of the tunnel dielectric layer 120. For example, the high-k dielectric layer 145 may include at least one of aluminum oxide (AlO), aluminum oxide (Al₂O₃), hafnium oxide (HfO₂), lanthanum oxide (La₂O₃), hafnium aluminum oxide (HfAlₓO_{y}), hafnium aluminate (HfAlON), hafnium silicate (HfSiₓO_{y}), hafnium silicon oxynitride (HfSiON), zirconium oxide (ZrO₂), zirconium silicate (ZrSiₓO_{y}), tantalum oxide (Ta₂O₃), titanium dioxide (TiO₂), lead zirconate titanate (PZT), lead titanate (PbTiO₃), lead zirconate (PbZrO₃), lead oxide (PbO), strontium titanium oxide (SrTiO₃), vanadium oxide (V₂O₅), barium strontium titanate (Ba,Sr)TiO₃ (BST), and strontium bismuth tantalate SrBi₂Ta₂O₉ (SBT). Since an electric field is inversely proportion to a dielectric constant, due to the high-k dielectric layer 145 having the higher dielectric constant, the intensity of the electric field generated in the blocking dielectric layer 140 may be less than the intensity of the electric field generated in the tunnel dielectric layer 120 in a program operation and/or an erase operation. As a result, it is possible to minimize the amount of charges tunneling the blocking dielectric layer 140 in the program operation and/or the erase operation.

The barrier dielectric layer 143 may include, for example, a dielectric material having an energy band gap greater than an energy band gap of the high-k dielectric layer 145. For example, the barrier dielectric layer 143 may include silicon oxide. However, exemplary embodiments of the inventive concept are not limited thereto. In an embodiment, the blocking dielectric layer 140 may consist of a single layer, or three or more layers.

According to an embodiment of the inventive concept, the top surface of the active region 103a may be, for example, arch-shaped and the uppermost portion of the active region 103a may be disposed at a level lower than the lowermost portion of the gate pattern 150. In this case, when the operation voltage is applied to the gate pattern 150, an electric field may focus on the uppermost portion of the center portion of the active region 103a. Accordingly, the intensity of the electric field provided to the uppermost portion of the center portion of the active region 103a may be greater than the intensity of the electric field provided to the edge area of the top surface of the active region 103a. That is, the uppermost portion of the center portion of the active region 103a may correspond to the electric field focusing region E.

If the intensity of the electric field at the edge area of the top surface of the active region 103a increases, charges stored in the charge storing pattern 130 on one active region may be readily spread into the charge storing pattern 130 on a neighboring active region. Thus, charge retention characteristic of a non-volatile memory device may deteriorate. However, according to exemplary embodiments of the inventive concept, the charges may be stored in the charge storing pattern 130 on the uppermost portion of the center portion of the active region 103a, and the amount of the charges stored in the charge storing pattern 130 on the edge area of the top surface of the active region 103a may be minimized. Accordingly, it is possible to minimize the phenomenon that the charges stored in the charge storing pattern 130 on the uppermost portion of the center portion of one active region 103a are spread into the charge storing pattern 130 on the neighboring active region 103a. As a result, a non-volatile memory device with increased reliability may be realized.

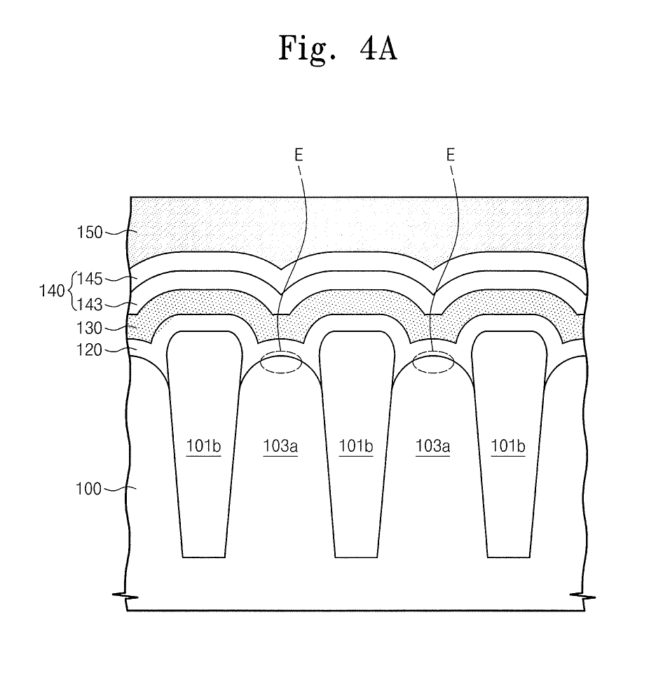

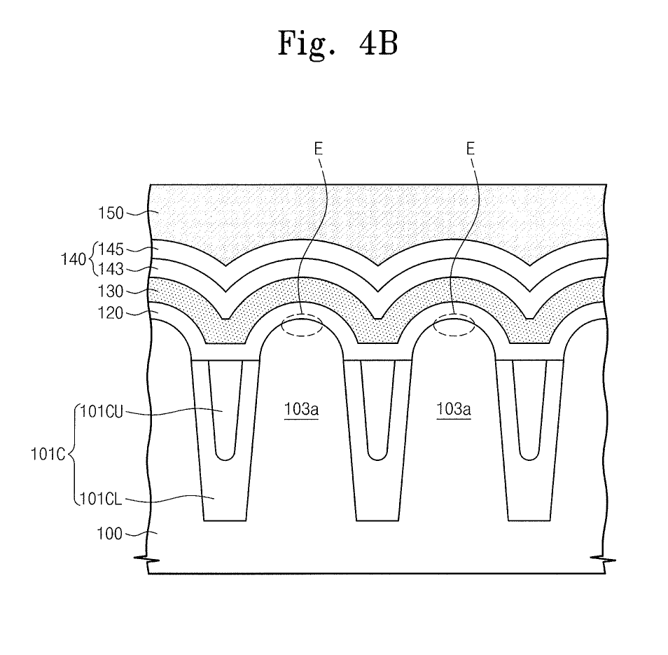

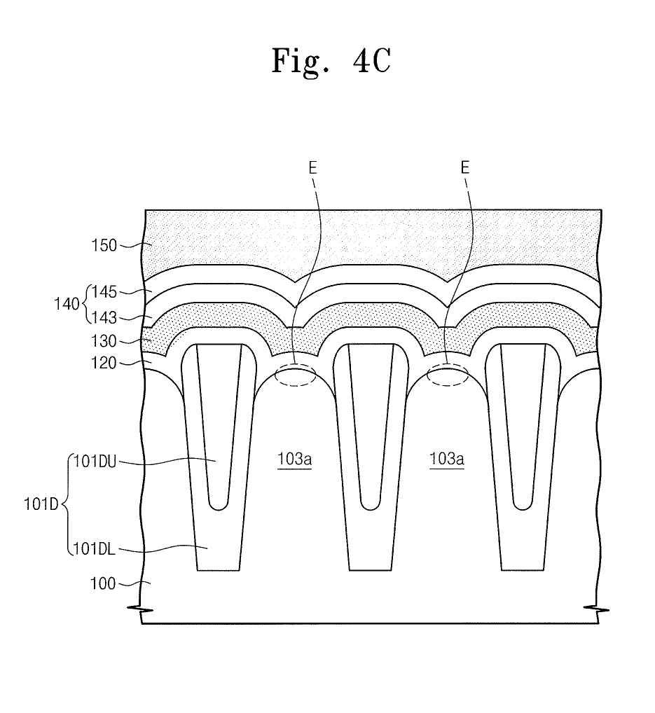

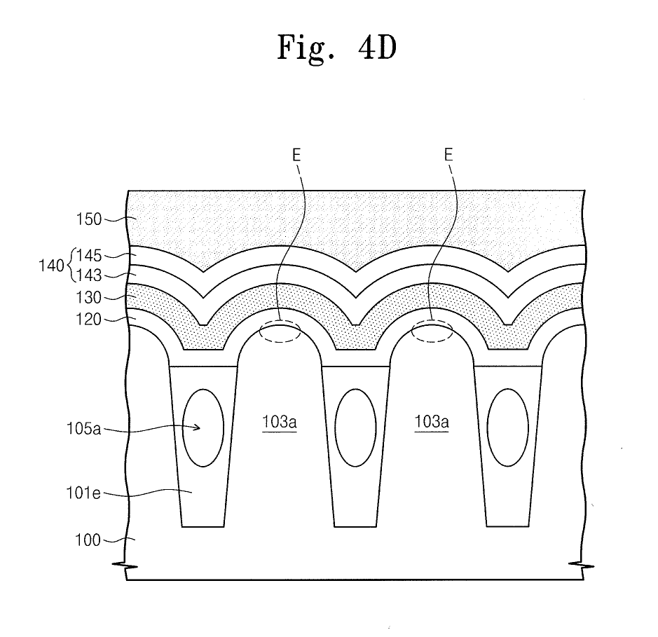

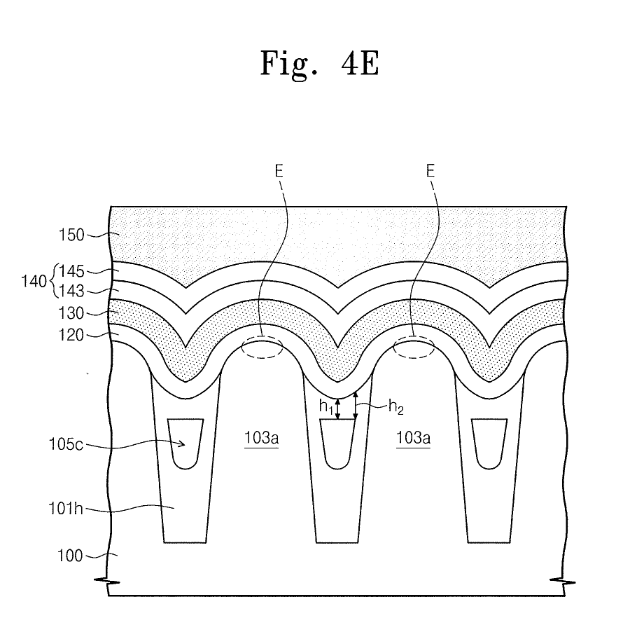

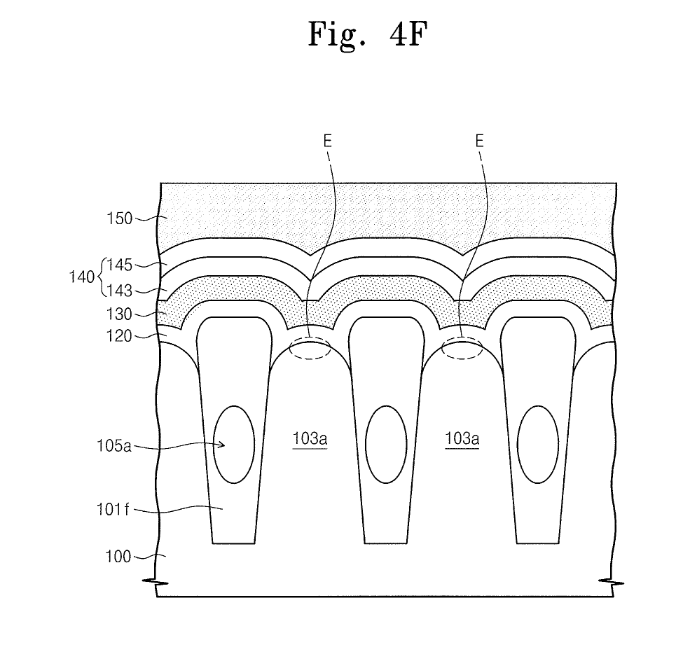

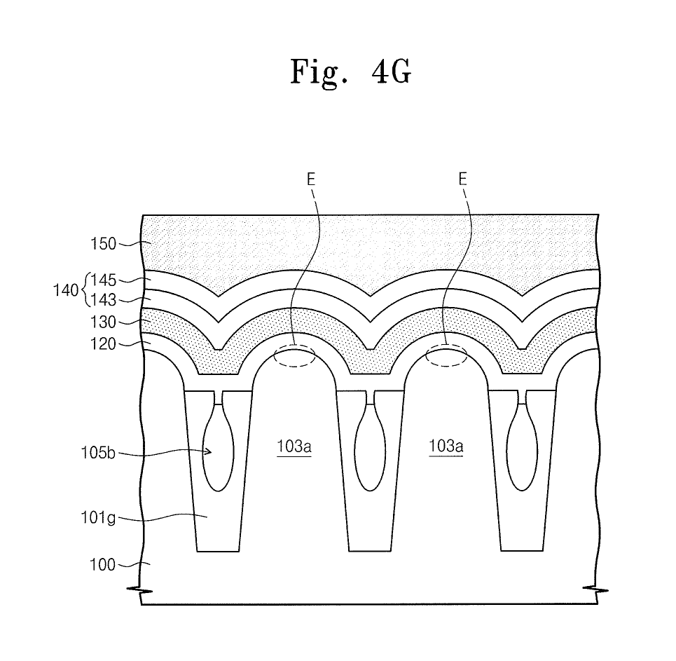

According to the above embodiment, the top surface of the device isolation pattern 101a may be disposed at, for example, a level lower than the top surface of the active region 103a. However, exemplary embodiments of the inventive concept are not limited thereto. The device isolation pattern may be formed in various shapes. The non-volatile memory device may include, for example, at least one of device isolation patterns 101b, 101C, 101D, 101e, 101f, 101g, and 101h illustrated in FIGS. 4A to 4G. Hereinafter, various examples of the device isolation pattern will be described in more detail with reference to drawings.

FIGS. 4A to 4G are cross-sectional views illustrating modified examples of a device isolation pattern in a non-volatile memory device according to an exemplary embodiment of the inventive concept.

Referring to FIG. 4A, a device isolation pattern 101b may be disposed in the substrate 100 to define the active region 103a. The device isolation pattern 101b may include, for example, a silicon oxide layer, a silicon nitride layer, and/or a silicon oxynitride layer. A top surface of the device isolation pattern 101b may be disposed at, for example, a level higher than the top surface of the active region 103a. According to the present embodiment, a top surface of the charge storing pattern 130 on the active region 103a may be disposed at, for example, a level lower than a top surface of the charge storing pattern 130 on the device isolation pattern 101b.

Referring to FIG. 4B, a top surface of a device isolation pattern 101C, which is disposed in the substrate 100 to define the active region 103a, may be disposed at, for example, a level lower than the uppermost portion of the active region 103a. The device isolation pattern 101C may include, for example, a first dielectric pattern 101CL and a second dielectric pattern 101CU. The first dielectric pattern 101CL may be disposed between the substrate 100 and the second dielectric pattern 101CU. That is, the second dielectric pattern 101CU may be spaced apart from the substrate 100 by the first dielectric pattern 101CL.

The first and second dielectric patterns 101CL and 101CU may include, for example, dielectric materials different from each other, respectively. In an embodiment, the second dielectric pattern 101CU may include, for example, a dielectric material having a dielectric constant less than that of the first dielectric pattern 101CL.

Referring to FIG. 4C, a top surface of a device isolation pattern 101D, which is disposed in the substrate 100 to define the active region 103a, may be disposed at, for example, a level higher than the uppermost portion of the active region 103a. A top surface of the charge storing pattern 130 on the active region 103a may be disposed at, for example, a level lower than a top surface of the charge storing pattern 130 on the device isolation pattern 101D. The device isolation pattern 101D may include, for example, a first dielectric pattern 101DL and a second dielectric pattern 101 DU. The first dielectric pattern 101DL may be disposed on the substrate 100 and the second dielectric pattern 101DU. That is, the second dielectric pattern 101DU may be spaced apart from the substrate 100 by the first dielectric pattern 101DL.

The first dielectric pattern 101DL and the second dielectric pattern 101DU may include, for example, dielectric materials different from each other, respectively. In an embodiment, the second dielectric pattern 101DU may include, for example, a dielectric material having a dielectric constant lower than that of the first dielectric pattern 101DL.

Referring to FIG. 4D, a device isolation pattern 101e may be disposed in the substrate to define the active region 103a. A top surface of the device isolation pattern 101e may be disposed at, for example, a level lower than the uppermost portion of the active region 103a. An air gap 105a may be disposed in the device isolation pattern 101e. A top end of the air gap 105a may be disposed, for example, at a level lower than the top surface of the device isolation pattern 101e. In other words, the air gap 105a may be completely surrounded by the device isolation pattern 101e. Accordingly, the air gap 105a may be completely closed by the device isolation pattern 101e. Additionally, the air gap 105a may be spaced apart from the tunnel dielectric layer 120 by the device isolation pattern 101e.

Referring to FIG. 4E, a device isolation pattern 101h may be disposed in the substrate 100 to define the active region 103a. An air gap 105c may be disposed in the device isolation pattern 101h. A top end of the air gap 105c may be disposed at, for example, a level lower than a top surface of the device isolation pattern 101h. That is, the air gap 105c may be completely surrounded by the device isolation pattern 101h. Accordingly, the air gap 105c may be completely closed by the device isolation pattern 101h. Additionally, the air gap 105c may be spaced apart from the tunnel dielectric layer 120 by the device isolation pattern 101h.

The top surface of the device isolation pattern 101h may have, for example, a concave shape toward the substrate 100. That is, a height of a center portion of the device isolation pattern 101h may be, for example, less than a height of an edge portion of the device isolation pattern 101h. The edge portion of the device isolation pattern 101h may be, for example, closer to the active region 103a as compared with the center portion of the device isolation pattern 101h. An entire top surface of the device isolation pattern 101h may have, for example, a rounded shape.

In an embodiment, a vertical distance from the top surface of the device isolation pattern 101h to the top end of the air gap 105c may, for example, become greater toward the active region 103a. Here, the vertical distance may be defined as a distance in a direction vertical to the top surface of the substrate 100. That is, a vertical distance h1 from the a top surface of the center portion of the device isolation pattern 101h to the top end of the air gap 105c may be, for example, less than a vertical distance h2 from a top surface of the edge portion of the device isolation pattern 101h to the top end of the air gap 105c. Thus, a distance between the tunnel dielectric layer 120 on the center portion of the device isolation pattern 101h and the air gap 105c may be less than a distance between the tunnel dielectric layer 120 on the edge portion of the device isolation pattern 101h and the air gap 105c.

Referring to FIG. 4F, the air gap 105a may be disposed in a device isolation pattern 101f according to the present modified embodiment, as described with reference to FIG. 4D. The air gap 105a may have, for example, the same shape as the air gap 105a described with reference to FIG. 4D. A top surface of the device isolation pattern 101f may be disposed at, for example, a level higher than the uppermost portion of the active region 103a, unlike the device isolation pattern 101e in FIG. 4D.

Referring to FIG. 4G, a device isolation pattern 101g may be disposed in the substrate 100 to define the active region 103a. An air gap 105b may be disposed in the device isolation pattern 101g. A part of the air gap 105b may be, for example, surrounded by the device isolation pattern 101g. In the words, a top end of the air gap 105b may be in an opened state from the device isolation pattern 101g. As a result, the top end of the air gap 105b may be closed by the tunnel dielectric layer 120.

However, the device isolation pattern in the non-volatile memory device according to exemplary embodiments of the inventive concept is not limited to the shapes described with reference to FIGS. 2 and 4A to 4G. Alternatively, for example, a top surface of the device isolation pattern may be disposed at substantially the same level as the uppermost portion of the active region 103a.

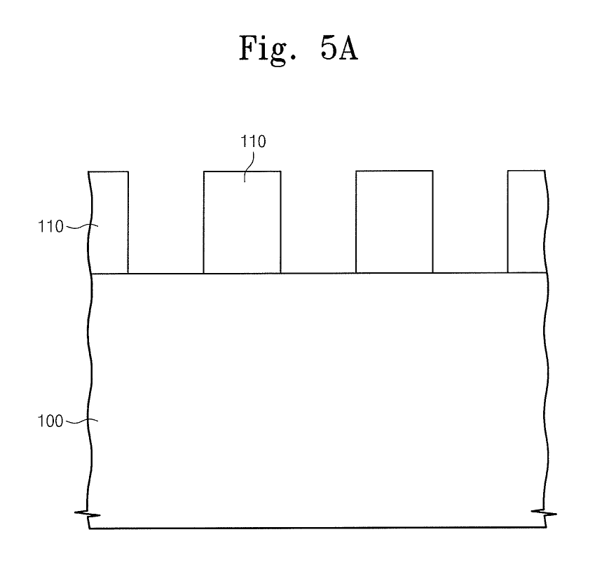

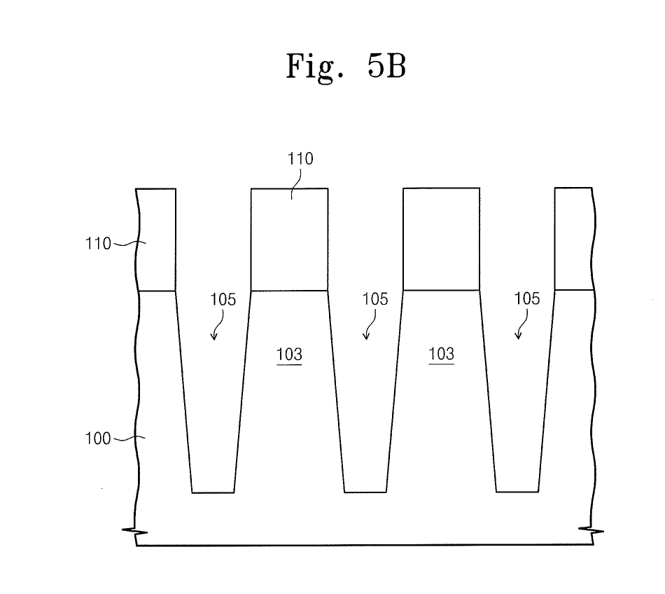

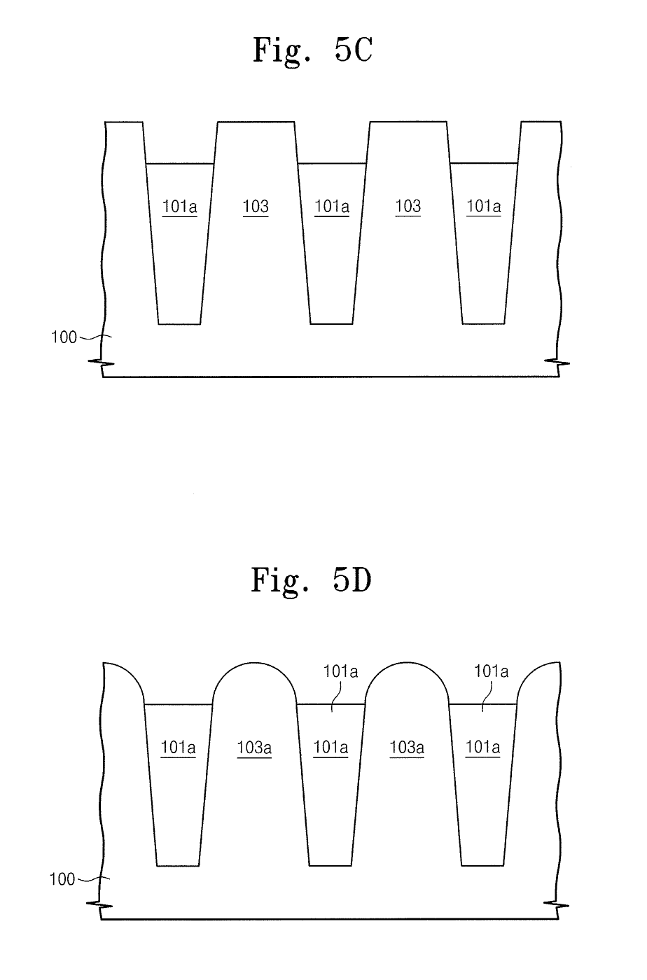

Hereinafter, a method of forming a non-volatile memory device according to an exemplary embodiment of the inventive concept will be described with reference to drawings. FIGS. 5A to 5D are cross-sectional views illustrating a method of forming the non-volatile memory device according to an exemplary embodiment of the inventive concept with reference to FIG. 2.

Referring to FIG. 5A, mask patterns 110 may be formed on a substrate 100. The mask patterns 110 may have, for example, line shapes extending in a first direction. The mask patterns 110 may be formed of a material having an etch selectivity with respect to the substrate 100. For example, when the substrate 100 is formed of single-crystalline silicon, each of the mask patterns 110 may include at least one of a silicon oxide layer, a silicon nitride layer, and a silicon oxynitride layer.

Referring to FIG. 5B, trenches 105 may be formed in the substrate 100. The trenches 105 may be formed, for example, by etching a portion of the substrate 100 exposed from the mask patterns 110 using the mask patterns 110 as etch masks. Preliminary active regions 103 may be defined by the trenches 105.

Referring to FIG. 5C, the mask patterns 110 may be removed, and then device isolation patterns 101a may be formed in the trenches 105, respectively. A device isolation layer may be formed on the substrate 100 to fill the trenches 105 and then the device isolation layer may be etched to form the device isolation patterns 101a. The device isolation layer may be etched until, for example, a top surface of the device isolation pattern 101a is disposed at a level lower than a top surface of the preliminary active region 103. The device isolation layer may be etched by at least one of, for example, a dry etching process, a wet etching process, and a chemical mechanical polishing process.

For example, referring to FIG. 5D, a thermal treatment process may be performed on the preliminary active regions 103 to form active regions 103a. Top surfaces of the active regions 103a may become, for example, rounded by the thermal treatment process. In an embodiment, an entire top surface of the active region 103a may be, for example, arch-shaped. Alternatively, the active regions 103a may be formed by, for example, performing an etching process on the top surfaces of the preliminary active regions 103. When the etching process is performed using an etchant selectively etching the material constituting the substrate 100, an etching rate of a top corner portion of the preliminary active region 103 may be, for example, greater than an etching rate of a flat top surface of the preliminary active region 103. Thus, the active regions 103a having rounded top surfaces may be formed.

Referring to FIG. 2 again, a tunnel dielectric layer 120, a charge storing pattern 130, and a blocking dielectric layer 140 may be formed to be sequentially stacked on the substrate 100. In an embodiments, the tunnel dielectric layer 120 may be formed to, for example, fully cover an exposed surface of the active region 103a. In an embodiment, the blocking dielectric layer 140 may include, for example, a barrier dielectric layer 143 and a high-k dielectric layer 145.

Gate patterns 150 may be formed on the blocking dielectric layer 140. The gate pattern 150 may have, for example, a line shape extending in a second direction. The second direction may cross the first direction. A conductive layer may be formed on the blocking dielectric layer 140 and then the conductive layer may be patterned to form the gate patterns 150.

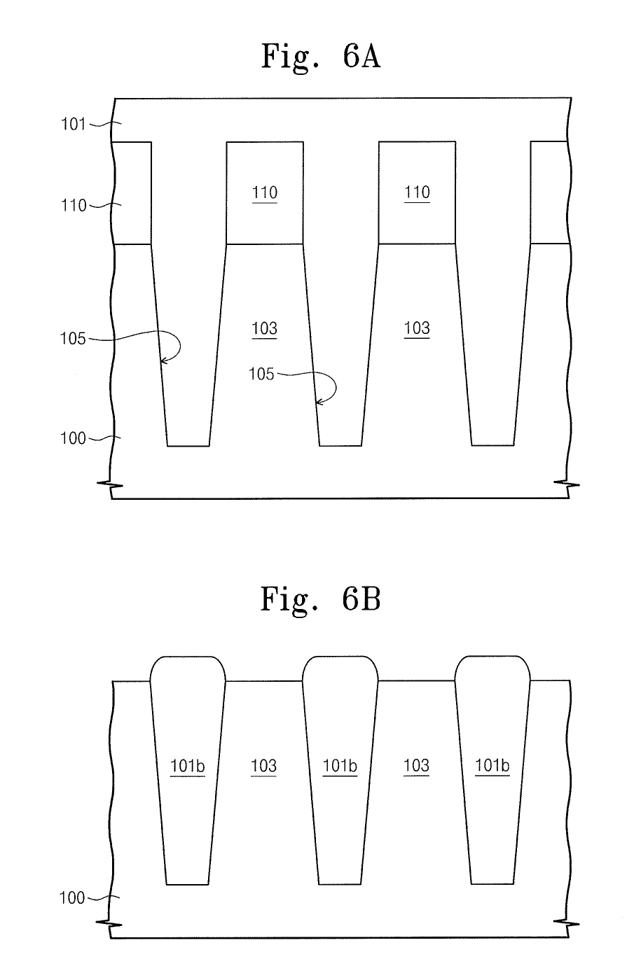

Hereinafter, a method of forming the non-volatile memory device illustrated in FIG. 4A will be described with reference to FIGS. 6A and 6B.

Referring to FIG. 6A, the substrate 100 may be etched using, for example, mask patterns 110 on the substrate 100 as etch masks to form trenches 105 defining preliminary active regions 103.

A device isolation layer 101 may be formed on the substrate 100 to fill the trenches 105.

Referring to FIG. 6B, the device isolation layer 101 may be etched to form device isolation patterns 101b and then the mask patterns 110 may be removed. The device isolation layer 101 may be etched until, for example, a level of a top surface of the device isolation pattern 101b is located between a level of a top surface of the preliminary active region 103 and a level of a top surface of the mask pattern 110. In an embodiment, the mask patterns 110 may be removed after the device isolation patterns 101b are formed.

As described with reference to FIG. 5D, the thermal treatment process or the etching process may be performed on the preliminary active region 103 to form an active region 103a. Due to the thermal treatment process or the etching process, the active region 103a having a rounded top surface may be foamed.

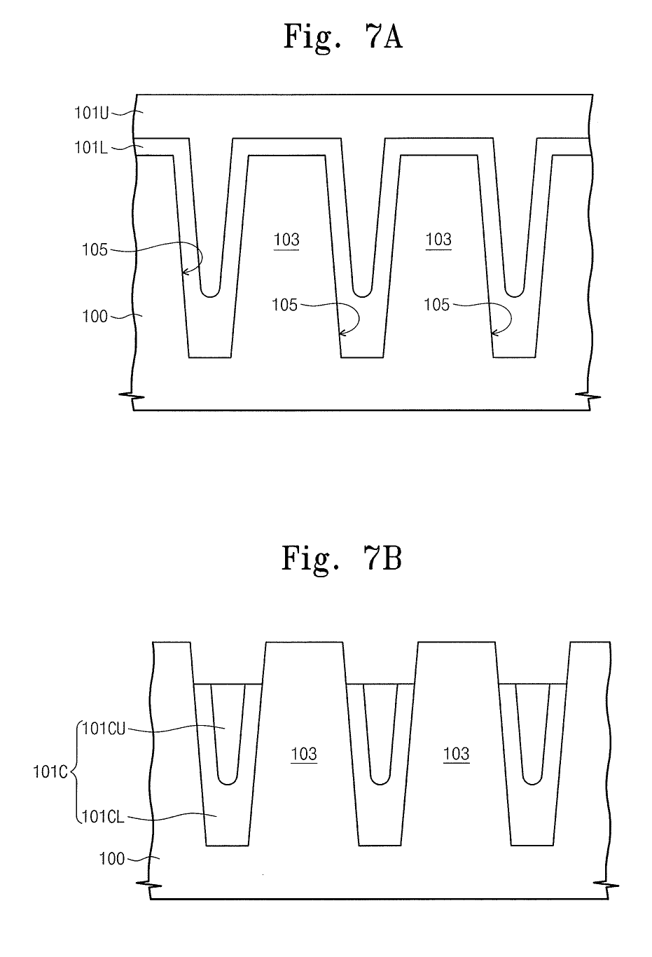

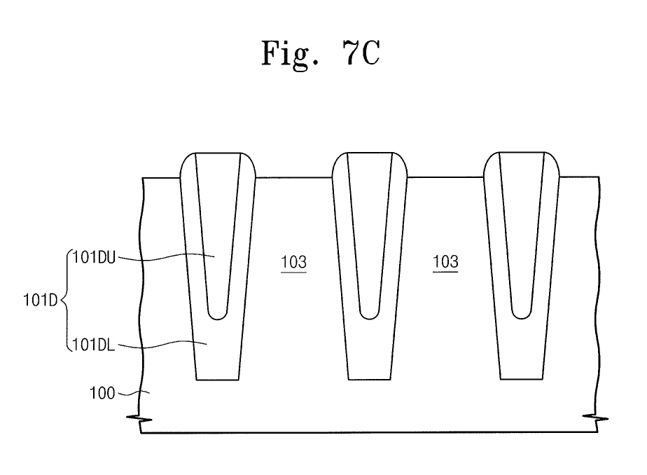

Methods of forming the non-volatile memory devices illustrated in FIGS. 4B and 4C will be described with reference to FIGS. 7A to 7C.

Referring to FIG. 7A, trenches 105 may be formed in the substrate 100. Preliminary active regions 103 may be defined by the trenches 105.

For example, a first dielectric layer 101L and a second dielectric layer 101U filling the trenches 105 may be formed on the substrate 100. The first dielectric layer 101L may cover, for example, inner surfaces of the trenches 105 and a top surface of the substrate 100. In an embodiment, inner spaces surrounded by the first dielectric layer 101L may be defined in the trenches 105, respectively. The second dielectric layer 101U may fill the inner spaces. The first and second dielectric layers 101L and 101U may include, for example, at least one of oxide, nitride, and oxynitride. In an embodiment, the first dielectric layer 101L and the second dielectric layer 101U may include dielectric materials different from each other, respectively. For example, the second dielectric layer 101U may be formed of a dielectric material having a dielectric constant different from that of the first dielectric layer 101L.

Referring to FIG. 7B, the first dielectric layer 101L and the second dielectric layer 101U may be etched to form device isolation patterns 101C in the trenches 105, respectively. The device isolation pattern 101C may include, for example, a first dielectric pattern 101CL and a second dielectric pattern 101CU. The first dielectric layer 101L and the second dielectric layer 101U may be etched until, for example, a level of a top surface of the device isolation pattern 101C becomes lower than a level of a top surface of the preliminary active region 103.

As described with reference to FIG. 5D, the thermal treatment process or the etching process may be performed on the preliminary active regions 103 to form active regions 103a. The active regions 103a having rounded top surfaces may be formed by the thermal treatment process or the etching process.

Alternatively, as illustrated in FIG. 7C, device isolation patterns 101D may be formed in the trenches 105, respectively. The device isolation pattern 101D may include, for example, a first dielectric pattern 101□L and a second dielectric pattern 101DU. A top surface of the device isolation pattern 101D may be disposed at, for example, a level higher than a top surface of the preliminary active region 103. In an embodiment, the device isolation patterns 101D may be formed before the mask patterns 110 used in a process of forming the trench 105 are removed. A first dielectric layer 101L and a second dielectric layer 101U may be formed to fill the trenches 105, and then the first dielectric layer 101L and the second dielectric layer 101U may be etched until, for example, a level of a top surface of the device isolation pattern 101D is disposed between a level of a top surface of the mask pattern 110 and a level of a top surface of the preliminary active region 103, thereby forming the device isolation patterns 101D. The thermal treatment process or the etching process described with reference to FIG. 5D may be used to form the structure of FIG. 4C.

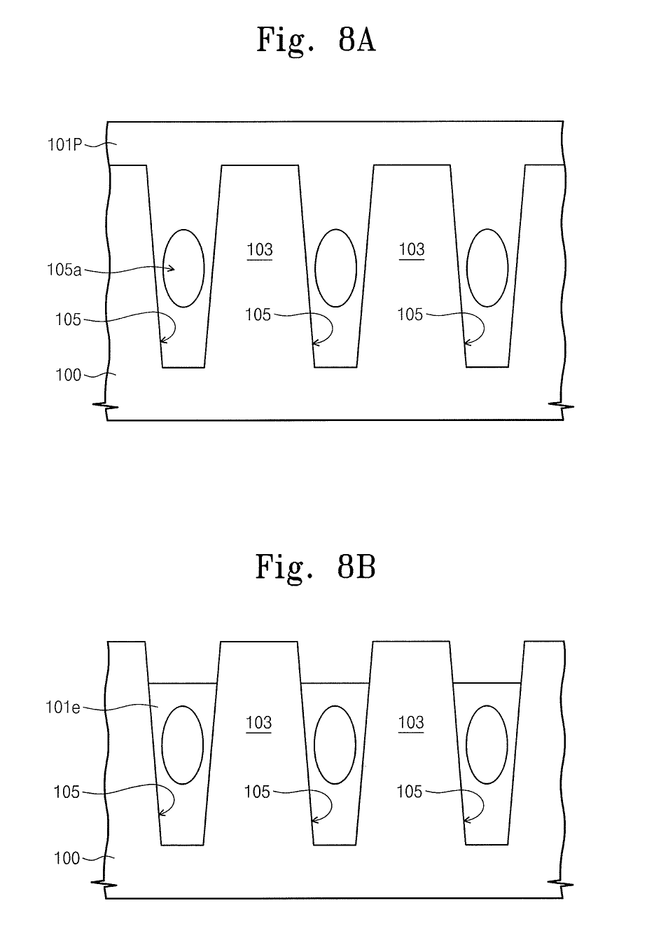

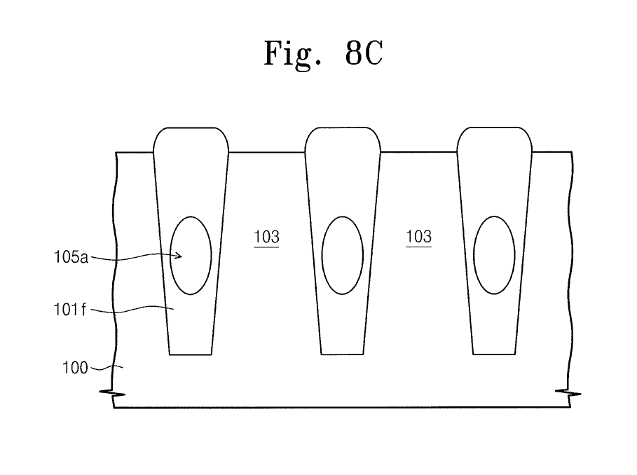

FIGS. 8A to 8C are cross-sectional views illustrating a method of forming the non-volatile memory devices described with reference to FIGS. 4D and 4F.

Referring to FIG. 8A, trenches 105 may be formed in the substrate 100. Preliminary active regions 103 may be defined by the trenches 105.

A device isolation layer 101P may be formed on the substrate 100 to partially fill the trenches 105. Due to the device isolation layer 101P, air gaps 105a may be formed in the trenches 105, respectively. In an embodiment, a top end of the air gap 105a may be formed to be disposed at, for example, a level lower than the top surface of the preliminary active region 103.

Referring to FIG. 8B, the device isolation layer 101P may be etched to form device isolation patterns 101e. A top surface of the device isolation pattern 101e may be disposed at, for example, a level lower than a top surface of the preliminary active region 103. In an embodiment, since the top end of the air gap 105a is disposed at, for example, the level lower than the top surface of the preliminary active region 103, the top end of the air gap 105a may be in a closed state by the device isolation pattern 101e. That is, the air gap 105a may be completely surrounded by the device isolation pattern 101e.

As described with reference to FIG. 5D, the thermal treatment process or the etching process may be performed on the preliminary active regions 103 to form active regions 103a. The active regions 103a having rounded top surfaces may be formed by the thermal treatment process or the etching process.

Alternatively, as illustrated in FIG. 8C, device isolation patterns 101f may be formed in the trenches 105, respectively. A device isolation layer filling the trenches 105 may be etched until, for example, a top surface of the device isolation pattern 101f is disposed at a level higher than the top surface of the preliminary active region 103, thereby forming the device isolation pattern 101f. Subsequently, the thermal treatment process or the etching process described with reference to FIG. 5D may be performed to form the structure of FIG. 4F.

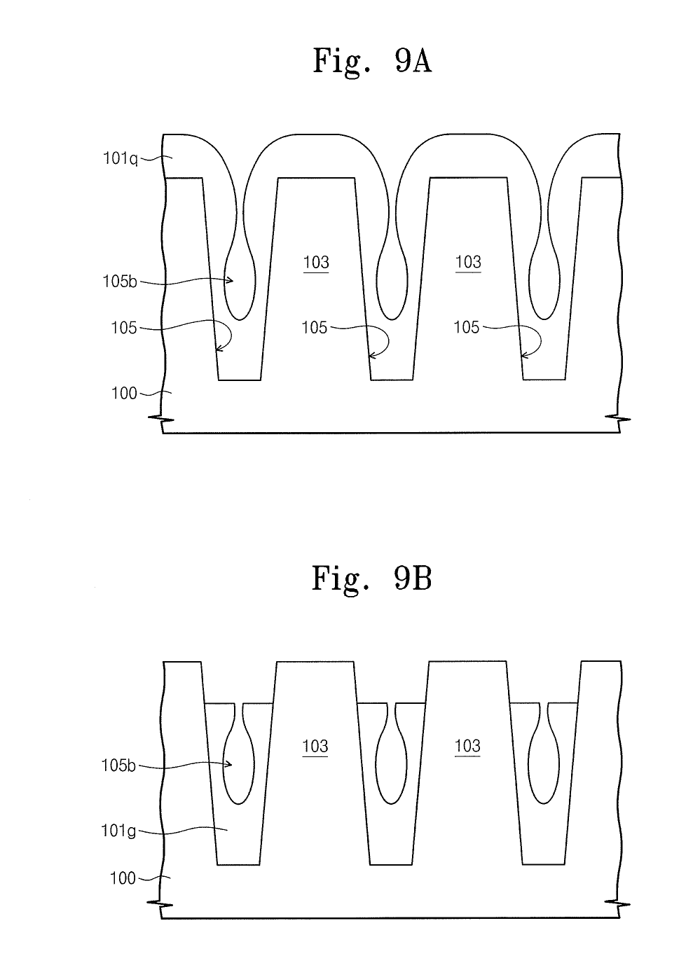

FIGS. 9A and 9B are cross-sectional views illustrating a method of forming the non-volatile memory device described with reference to FIG. 4G.

Referring to FIG. 9A, trenches 105 may be formed in the substrate 100. Preliminary active regions 103 may be defined by the trenches 105. A device isolation layer 101q may be formed on the substrate 100 to partially fill the trenches. Air gaps 105b defined by the device isolation layer 101q may be formed in the trenches 105, respectively.

Referring to FIG. 9B, the device isolation layer 101q may be etched to from device isolation patterns 101g in the trenches 105, respectively. A top surface of the device isolation pattern 101g may be disposed at, for example, a level lower than the top surface of the preliminary active region 103. A part of the air gap 105b may be, for example, surrounded by the device isolation pattern 101g. A top end of the air gap 105b may be in an opened state.

As described with reference to FIG. 5D, the thermal treatment process or the etching process may be performed on the preliminary active regions 103 to form active regions 103a. The active regions 103a having rounded top surfaces may be formed by the thermal treatment process or the etching process.

However, a method of forming the device isolation patterns in the non-volatile memory devices according to exemplary embodiments are not be limited to the above methods. The device isolation patterns may be formed by various methods. For example, a device isolation layer filling the trenches may be etched until the top surfaces of the preliminary active regions are exposed, thereby forming the device isolation patterns. In this case, the top surfaces of the device isolation patterns may be disposed at substantially the same level as the top surfaces of the preliminary active regions.

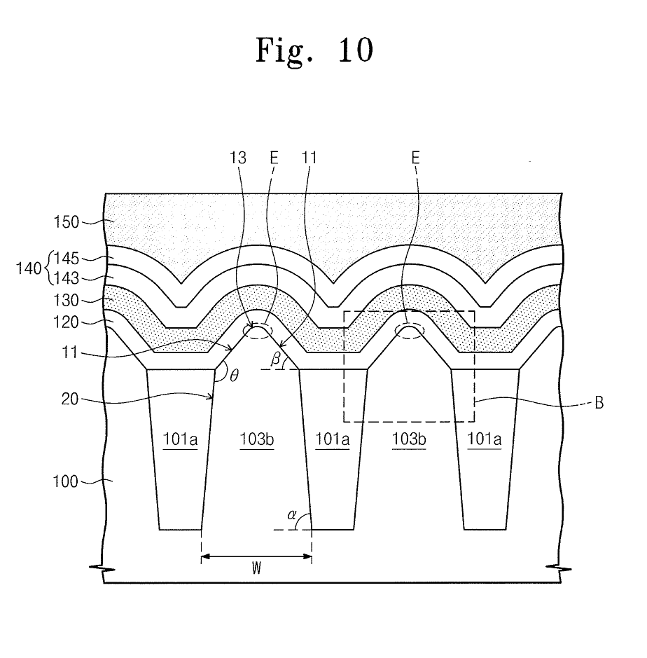

Hereinafter, a non-volatile memory device according to an exemplary embodiment of the inventive concept will be described with reference to the drawings. FIG. 10 is a cross-sectional view illustrating a non-volatile memory device according to an exemplary embodiment of the inventive concept.

Referring to FIG. 10, device isolation patterns 101a may be disposed in a substrate 100 to define active regions 103b. The active regions 103b may have, for example, line shapes extending in the same first direction as the active regions 103a described with reference to FIG. 1. In an embodiment, the active region 103b may be, for example, a portion of the substrate surrounded by the device isolation patterns 101a.

The uppermost portion of the active region 103b may be the uppermost portion of a center portion of the active region 103b. The uppermost portion of the center portion of the active region 103b may be an electric field focusing region E. That is, the electric field focusing region E and a portion of the active region 103b under the electric field focusing region E may correspond to the center portion of the active region 103b. The portion of the active region 103b except the center portion may be an edge portion of the active region 103b.

A top surface of the active region 103b may include, for example, a center area 13 and a pair of first surfaces 11. The center area 13 of the top surface of the active region 103b may be disposed between the pair of first surfaces 11. The first surfaces 11 may connect the center area 13 of the top surface of the active region 103b to a pair of sidewalls 20 of the active region 103b, respectively. For example, with respect to a plane parallel to the top surface of the substrate 100, the sidewall 20 of the active region 103b may have a first angle α greater than about 0 degrees and less than about 180 degrees, and the first surface 11 of the active region 103b may have a second angle β greater than about 0 degrees and less than about 180 degrees. In an embodiment, an absolute value of the first angle α may be, for example, greater than an absolute value of the second angle. Thus, a third angle θ between each of the first surfaces 11 and each of the sidewalls 20 of the active region 103b may be, for example, equal to or greater than about 90 degrees and less than about 180 degrees.

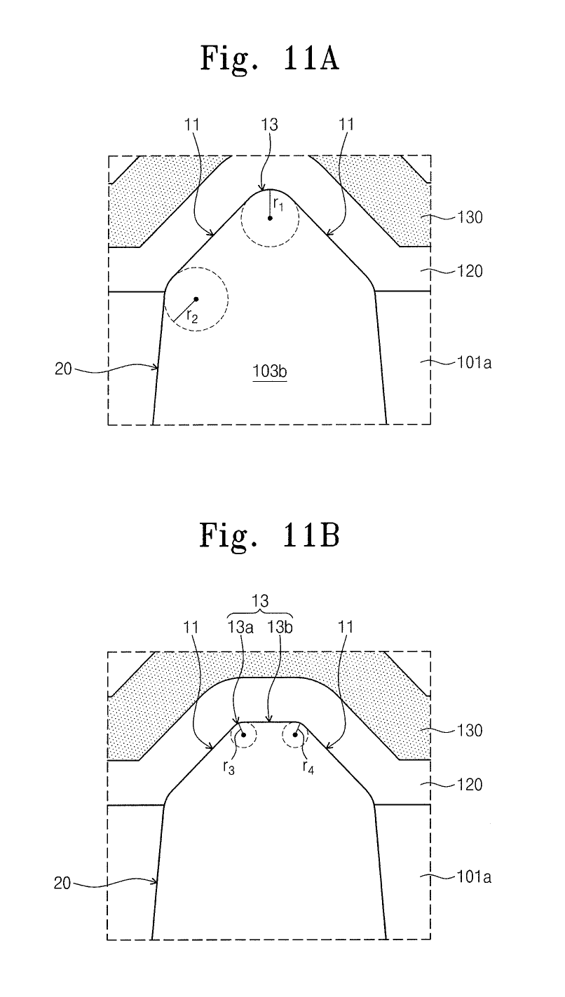

The first surfaces 11, the sidewalls 20, and the center area 13 of the top surface of the active region 103b joining the first surfaces 11 may be realized in various shapes. Hereinafter, the first surfaces 11, the sidewalls 20, and the center area 13 of the top surface of the active region 103b will be described with reference to the drawings. FIGS. 11A and 11B are enlarged views illustrating a portion ‘B’ of FIG. 10.

Referring to FIG. 11A, an entire center area 13 of the top surface of the active region 103b may have, for example, a rounded shape. That is, the electric field focusing region E disposed at the uppermost portion of the center portion of the active region 103b may have, for example, a rounded top surface. In an embodiment, the rounded top surface may be formed by, for example, a thermal treatment process.

In an embodiment, the center area 13 of the top surface of the active region 103b may be, for example, arch-shaped. The center area 13 of the top surface of the active region 103b may have a radius curvature r1. Connection surfaces of the first surfaces 11 and the sidewalls 20 may have, for example, a round-shaped. Each of the rounded connection surfaces may have a second radius curvature r2.

In an embodiment, the first radius curvature r1 and/or the second radius curvature r2 may be, for example, less than a half of a width W of the active region 103b. For example, the first radius curvature r1 and/or the second radius curvature r2 may be greater than about 0 nm and equal to or less than about 5 nm. The width W of the active region 103b may be defined as a maximum horizontal distance between the pair of sidewalls 20 included in one active region 103b.

Alternatively, referring to FIG. 11B, the center area 13 of the top surface of the active region 103b may include, for example, a second surface 13b and connection surfaces 13a between the second surface 13b and the first surfaces 11. The second surface 13b may be, for example, parallel to the top surface of the substrate 100. The connection surfaces 13a may be, for example, rounded. The rounded connection surfaces 13a may have a third radius curvature r3 and a fourth radius curvature r4, respectively. Each of the third radius curvature r3 and the fourth radius curvature r4 may be, for example, less than a half of the width W of the active region 103b. For example, each of the third radius curvature r3 and a fourth radius curvature r4 may be greater than about 0 nm and equal to or less than about 5 nm.

The rounded top surface may be, for example, anisotropically etched by a thermal treatment process or an etching process, thereby forming the second surface 13b parallel to the top surface of the substrate 100. According to the present embodiment, it is possible to increase an area of a channel generated in the center area 13 of the top surface of the active region 103b. Thus, a cell current of the non-volatile memory device may increase.

The uppermost portion of the active region 103b may be disposed at, for example, a level higher than a top surface of the device isolation pattern 101a. However, the shape of the device isolation pattern 101a is not limited thereto. The non-volatile memory device according to the present embodiment may include at least one of the device isolation patterns described with reference to FIGS. 4A to 4G.

A gate pattern 150 extending in a second direction may be disposed on the substrate 100. The second direction may be, for example, perpendicular to the first direction. The lowermost portions of the gate pattern 150 may be disposed at, for example, a level higher than the uppermost portion of the active region 103b. That is, the lowermost portions of the gate pattern 150 may be disposed at, for example, a level higher than the electric field focusing region E of the active region 103b.

When an operation voltage is applied to the gate pattern 150, an electric field may focus on the electric field focusing region E of the active region 103b. As a result, the intensity of the electric field in the electric field focusing region E of the active region 103b may be greater than the intensity of the electric field in a top surface of the edge portion of the active region 103b.

A charge storing pattern 130 may be disposed between the substrate 100 and the gate pattern 150. In an embodiment, the uppermost portion of the charge storing pattern 130 may be disposed at, for example, a level lower than the lowermost portion of the gate pattern 150.

A tunnel dielectric layer 120 may be disposed between the active region 103b and the charge storing pattern 130. A blocking dielectric layer 140 may be disposed between the charge storing pattern 130 and the gate pattern 150. The blocking dielectric layer 140 may include, for example, a barrier dielectric layer 143 and a high-k dielectric layer 145.

The non-volatile memory device according to the present embodiment may have substantially the same effects as the non-volatile memory device described in connection with FIG. 1.

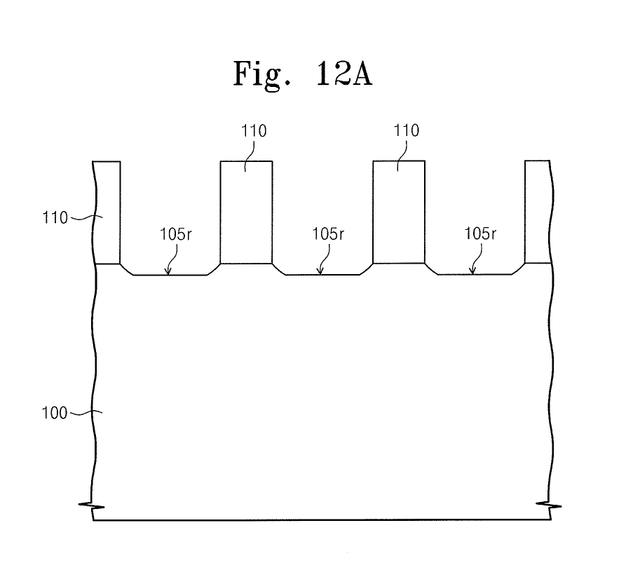

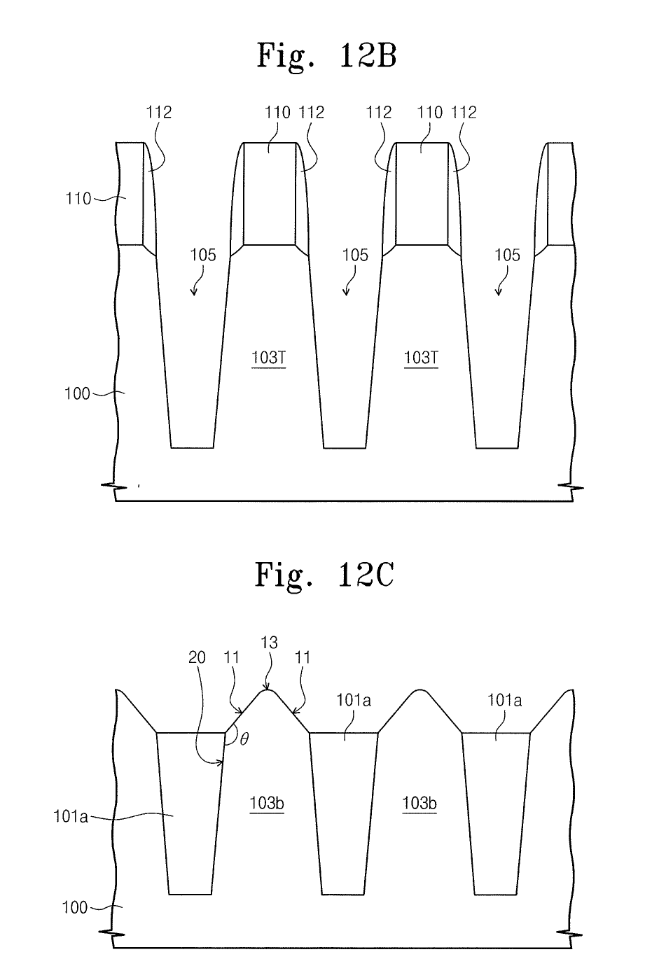

Hereinafter, a method of forming a non-volatile memory device according to an exemplary embodiment of the inventive concept will be described with reference to the FIGS. 12A to 12C. FIGS. 12A to 12C are cross-sectional views illustrating a method of forming a non-volatile memory device according to an exemplary embodiment of the inventive concept.

Referring to FIG. 12A, mask patterns 110 may be formed on the substrate 100. The mask patterns 110 may be formed to have, for example, line shapes extending in the first direction. The mask patterns 110 may be formed of a material having an etch selectivity with respect to the substrate 100.

Recess regions 105r may be formed in the substrate 100. The recess regions 105r may be formed by, for example, etching portions of the substrate 100 using the mask patterns 110 as etch masks. In an embodiment, the recess regions 105r may be formed by, for example, a first dry etching process.

Referring to FIG. 12B, spacers 112 may be formed on sidewalls of the mask patterns 110. The spacers 112 may cover portions of inner surfaces of the recess regions 105r and the sidewalls of the mask patterns 110. For example, a spacer layer may be conformally formed on the substrate 100 having the mask patterns 110 and then the spacer layer may be etched until top surfaces of the mask patterns 110 and the other portions of the inner surfaces of the recess regions 105r are exposed, thereby forming the spacers 112.

Trenches 105 may be formed in the substrate 100. The trenches 105 may be formed by, for example, etching portions of the substrate 100 using the mask patterns 110 and the spacers 112 as etch masks. Preliminary active regions 103T may be defined by the trenches 105.

In an embodiment, the trenches 105 may be formed by, for example, a second dry etching process. The first dry etching process may create more by-products than the second dry etching process. By-products created by a dry etching process may be formed on a sidewall of an etching object to be used as passivation materials. Thus, the etching object may be formed to have an inclined sidewall. Since the first dry etching process may create more by-products than the second dry etching process, an angle of the sidewall of the trench 105 based on a plane parallel to the top surface of the substrate 100 may be greater than an angle of the sidewall of the recess region 105r based on the plane parallel to the top surface of the substrate 100. In other words, the sidewall of the trench 105 may be more vertical to the substrate 100 than the sidewall of the recess region 105r.

In an embodiment, the preliminary active regions 103T may have, for example, an inclined surface in contact with the spacer 112. The inclined surface may correspond to a portion of the inner surface of the recess region 105r.

Referring to FIG. 12C, the mask patterns 110 and the spacers 112 may be removed. Also, device isolation patterns 101a may be formed in the trenches 105, respectively. A device isolation layer may be formed to fill the trenches 105 and then the device isolation layer may be etched to form the device isolation patterns 101a. The device isolation layer may be etched until, for example, the top surface of the device isolation patterns 101a are lower than the top surfaces of preliminary active regions 103T, thereby forming the device isolation patterns 101a.

The thermal treatment process or the etching process described with reference to FIG. 5D may be performed on the preliminary active regions 103T to form active regions 103b. Center areas 13 of top surfaces of the active regions 103b may be rounded by the thermal treatment process or the etching process described with reference to FIG. 5D. The top surface of the active region 103b may include, for example, first surfaces 11 and the first surfaces 11 may connect the center area 13 to sidewalls 20 of the active region 103b, respectively. With respect to a plane parallel to the top surface of the substrate 100, the sidewall 20 of the active region 103b may have, for example, a first angle greater than about 0 degrees and less than about 180 degrees and the first surface 11 of the top surface of the active region 103b may have a second angle greater than about 0 degrees and less than about 180 degrees. In an embodiment, the absolute value of the first angle may be, for example, greater than the second angle. Thus, a third angle θ between the first surface 11 and the sidewall 20 may be, for example, equal to or greater than about 90 degrees and less than about 180 degrees.

In an embodiment, an anisotropic etching process may further performed on the rounded center area 13 of the top surface of the active region 103b after the thermal treatment process or the etching process described with reference to FIG. 5D is performed. In this case, the center area 13 of the top surface of the active region 103b, as illustrated in FIG. 11B, may be formed to have, for example, a second surface 13b parallel to the top surface of the substrate 100 and connection surfaces 13a connecting the second surface 13b to the first surfaces 11. The connection surfaces 13a may be, for example, rounded. The rounded connection surfaces 13a may have the third radius curvature r3 and the fourth radius curvature r4, respectively. Each of the third radius curvature r3 and the fourth radius curvature r4 may be, for example, less than a half of the width W of the active region 103b. For example, each of the third radius curvature r3 and a fourth radius curvature r4 may be, for example, greater than about 0 nm and equal to or less than about 5 nm. According to the present embodiment, it is possible to increase an area of a channel generated in the center area 13 of the top surface of the active region 103b. Thus, a cell current of the non-volatile memory device may increase.

Referring to FIG. 10 again, a tunnel dielectric layer 120, a charge storing pattern 130 and a blocking dielectric layer 140 may be sequentially formed on the substrate 100. In an embodiment, the blocking dielectric layer 140 may include, for example, a barrier dielectric layer 143 and a high-k dielectric layer 145. A gate pattern 150 may be formed on the blocking dielectric layer 140.

The non-volatile memory device according to the present embodiment may have substantially the same effects as the non-volatile memory device described in connection with FIG. 1.

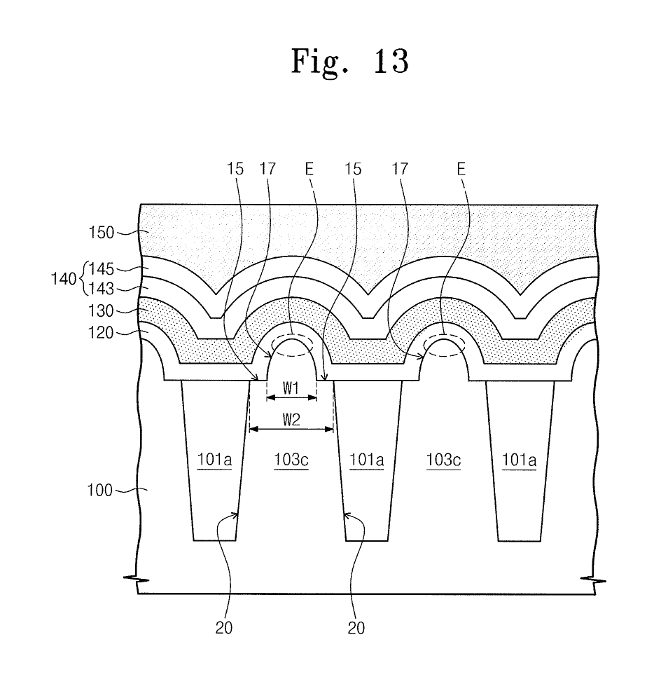

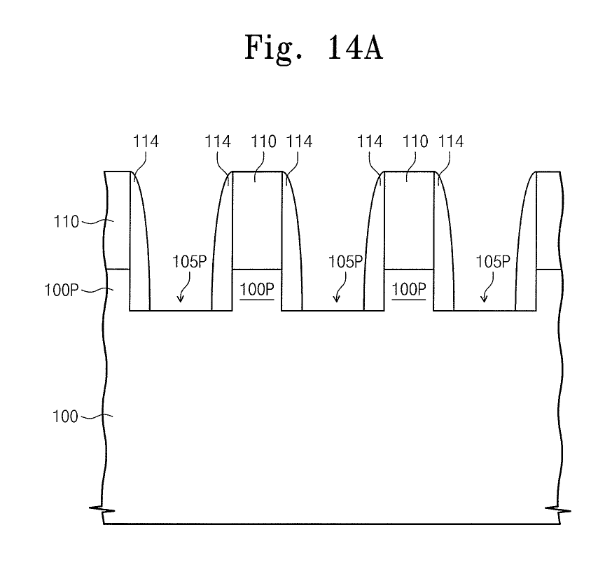

Hereinafter, a non-volatile memory device according to an exemplary embodiment of the inventive concept will be described with reference to the drawings. FIG. 13 is a cross-sectional view illustrating a non-volatile memory device according to an exemplary embodiment of the inventive concept.

Referring to FIG. 13, device isolation patterns 101a may be disposed in the substrate 100 to define active regions 103c. The active regions 103c may have, for example, line shapes extending in a first direction. The active region 103c may correspond to a portion of the substrate 100 surrounded by the device isolation patterns 101a.

For example, a top surface of the active region 103c may include a pair of first surfaces 15 and a center area 17 disposed between the pair of first surfaces 15. The first surfaces 15 may extend, for example, in parallel to the top surface of the substrate 100 from sidewalls 20 of the active region 103c toward the center area 17 of the top surface of the active region 103c. The center area 17 of the top surface of the active region 103c may be, for example, connected to the first surfaces 15, and the center area 17 of the top surface of the active region 103c may protrude upwardly above the first surfaces 15.

In an embodiment, a maximum width W1 in a second direction of the center area 17 of the top surface of the active region 103c may be, for example, less than a minimum width W2 between the sidewalls 20 of the active region 103c. The second direction may cross the first direction.

The center area 17 of the top surface of the active region 103c may be, for example, rounded. In an embodiment, the center area 17 of the top surface of the active region 103c may be, for example, arch-shaped. The center area 17 of the top surface of the active region 103c may have a predetermined radius curvature. For example, the center area 17 of the top surface of the active region 103c may have a radius curvature greater than about 0 nm and equal to or less than about 5 nm. In an embodiment, a portion of the active region 103c surrounded by the center area 17 of the top surface of the active region 103c may include, for example, the uppermost portion of the active region 103c. The uppermost portion of the active region 103c may correspond to an electric field focusing region E.

The uppermost portion of the active region 103c may be disposed at, for example, a level higher than the top surface of the device isolation pattern 101a. However, the shape of the device isolation pattern 101a is not limited thereto. The non-volatile memory device according to the present embodiment may include at least one of the device isolation patterns according to various examples described with reference to FIGS. 4A to 4G.

A gate pattern 150 may be disposed on the substrate 100 to extend in the second direction. The lowermost portions of the gate pattern 150 may be disposed at, for example, a level higher than the uppermost portion of the active region 103c. In other words, the lowermost portions of the gate pattern 150 may be disposed at, for example, a level higher than the electric field focusing region E.

According to the present embodiment, when an operation voltage is applied to the gate pattern 150, an electric field may focus on the electric field focusing region E of the active region 103c. As a result, the intensity of the electric field in the electric field focusing region E of the active region 103c may be greater than the intensity of the electric field in another portion of the active region 103c.

A charge storing pattern 130 may be disposed between the substrate 100 and the gate pattern 150. In an embodiment, the uppermost portion of the charge storing pattern 130 may be disposed at, for example, a level lower than the lowermost portion of the gate pattern 150.

A tunnel dielectric layer 120 may be disposed between the active region 103c and the charge storing pattern 130. A blocking dielectric layer 140 may be disposed between the charge storing pattern 130 and the gate pattern 150. The blocking dielectric layer 140 may include, for example, a barrier dielectric layer 143 and a high-k dielectric layer 145.

The non-volatile memory device according to the present embodiment may have substantially the same effects as the non-volatile memory device described in connection with FIG. 1.

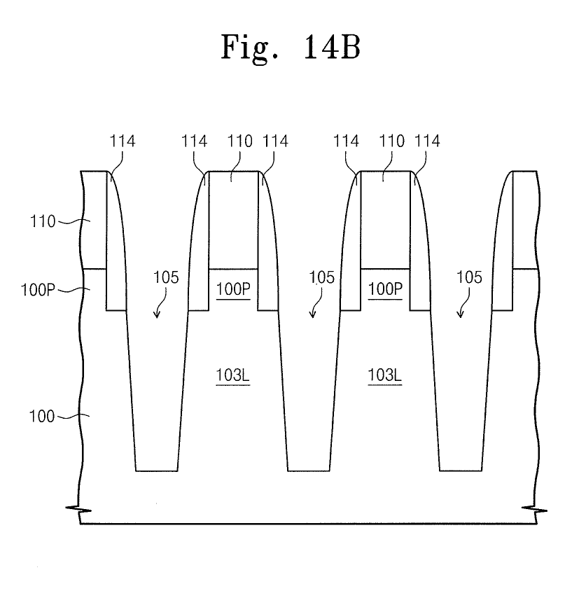

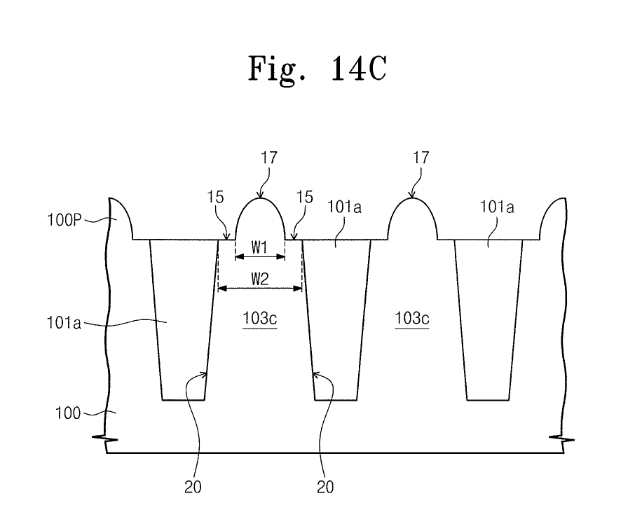

Hereinafter, a method of forming a non-volatile memory device according to an exemplary embodiment of the inventive concept will be described with reference to the FIGS. 14A to 14C. FIGS. 14A to 14C are cross-sectional views illustrating a method of forming a non-volatile memory device according to an exemplary embodiment of the inventive concept.

Referring to FIG. 14A, mask patterns 110 may be formed on the substrate 100. The mask patterns 110 may have, for example, line shapes extending in the first direction.

Preliminary trenches 105P may be formed in the substrate 100. The preliminary trenches 105P may be formed by, for example, etching portions of the substrate 100 using the mask patterns 110 as etch masks.

According to an embodiment, the preliminary trenches 105P may be formed by, for example, a third dry etching process. The third dry etching process may create lesser by-products than the first dry etching process for forming the recess regions 105r described with reference to FIGS. 12A and 12B. In other words, since the by-products used as a passivation material may be minimized due to the third dry etching process, the preliminary trench 105P may have sidewalls substantially vertical to the substrate 100.

A protrusion 100P may be defined under each of the mask patterns 110 by the preliminary trenches 105P. The protrusion 100P may protrude above a bottom surface of the preliminary trench 105P.

Spacers 114 may be formed on sidewalls of the mask patterns 110. The spacer 114 may cover a sidewall and a portion of the bottom of the preliminary trench 105P. In other words, the spacers 114 may cover sidewalls of the protrusions 100P. A spacer layer may be, for example, conformally formed on the substrate 100 including the preliminary trenches 105P and then the spacer layer may be anisotropically etched until top surfaces of the mask patterns 110 and portions of the bottom surfaces of the preliminary trenches 105P are exposed.

Referring to FIG. 14B, trenches 105 may be formed in the substrate 100. The trenches 105 may be formed by, for example, etching an exposed substrate 100 using the mask patterns 110 and the spacers 114 as etch masks. Preliminary active regions 103L may be defined by the trenches 105. The preliminary active region 103L may include, for example, the protrusion 100P.

Referring to FIG. 14C, the mask patterns 110 and the spacers 114 may be removed. Device isolation patterns 101a may be formed in the trenches 105, respectively. A device isolation layer may be formed on the substrate 100 to fill the trenches 105 and then the device isolation layer may be etched to from the device isolation patterns 101a. The device isolation layer may be etched until, for example, the device a top surface of isolation pattern 101a is lower than the uppermost top surface of the preliminary active region 103L.

The thermal treatment process or the etching process described with reference to FIG. 5D may be performed on the preliminary active regions 103L to faun active regions 103c. The top surface of the active region 103c may include, for example, a pair of first surfaces 15 and a center area 17 disposed between the pair of first surfaces 15. The first surfaces 15 may extend, for example, in parallel to the top surface of the substrate 100 from sidewalls 20 of the active region 103c toward a center portion of the active region 103c. The center area 17 of the top surface of the active region 103c may be, for example, connected to the first surfaces 15, and the center area 17 of the top surface of the active region may protrude upwardly above the first surfaces 15. The center area 17 of the top surface of the active region 103c may be formed by, for example, performing the thermal treatment or the etching process on a top surface of the protrusion 100P of the preliminary active region 103L. In the words, the center area 17 of the top surface of the active region 103c may be rounded by the thermal treatment process or the etching process. The center area 17 of the top surface of the active region 103c may have, for example, a radius curvature greater than about 0 nm and equal to or less than about 5 nm.

In an embodiment, a maximum width W1 in a second direction of the center area 17 of the top surface of the active region 103c may be, for example, less than a minimum width W2 between the sidewalls 20 of the active region 103c. The second direction may cross the first direction.

Referring to FIG. 13 again, a tunnel dielectric layer 120, a charge storing pattern 130, and a blocking dielectric layer 140 may be formed to be sequentially stacked on the substrate 100. In an embodiment, the blocking dielectric layer 140 may include, for example, a barrier dielectric layer 143 and the high-k dielectric layer 145. A gate pattern 150 may be formed on the blocking dielectric layer 140.

The non-volatile memory device according to the present embodiment may have substantially the same effects as the non-volatile memory device described in connection with FIG. 1.

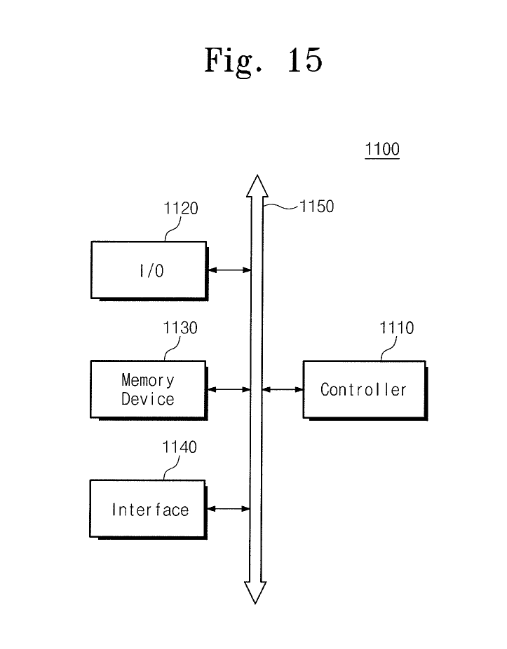

FIG. 15 is a schematic block diagram illustrating an example of electronic systems including non-volatile memory devices according to exemplary embodiments of the inventive concept.

Referring to FIG. 12, an electronic system 1100 according to an embodiment of the inventive concept may include, for example, a controller 1110, an input/output (I/O) unit 1120, a memory device 1130, an interface unit 1140 and a data bus 1150. At least two of the controller 1110, the I/O unit 1120, the memory device 1130 and/or the interface unit 1140 may communicate with each other through the data bus 1150. The data bus 1150 may correspond to a path through which electrical signals are transmitted.

The controller 1110 may include at least one of, for example, a microprocessor, a digital signal processor, a microcontroller or another logic device. The other logic device may have a similar function to any one of the microprocessor, the digital signal processor and the microcontroller. The I/O unit 1120 may include, for example, a keypad, a keyboard and/or a display unit. The memory device 1130 may store data and/or commands. The memory device 1130 may include at least one of the non-volatile memory devices according to exemplary embodiments described above. The memory device 1130 may further include another type of semiconductor memory device which is different from the semiconductor devices described above. For example, the memory device 1130 may further include a non-volatile memory device (e.g. a magnetic memory device, a phase change memory device, etc), a dynamic random access memory (DRAM) device and/or a static random access memory (SRAM) device. The interface unit 1140 may transmit electrical data to a communication network or may receive electrical data from a communication network. The interface unit 1140 may operate by wireless or cable. For example, the interface unit 1140 may include an antenna for wireless communication or a transceiver for cable communication. Although not shown in the drawings, the electronic system 1100 may further include, for example, a fast DRAM device and/or a fast SRAM device which acts as a operation memory device for increasing an operation of the controller 1110.

The electronic system 1100 may be applied to, for example, a personal digital assistant (PDA), a portable computer, a web tablet, a wireless phone, a mobile phone, a digital music player, a memory card or other electronic products. The other electronic products may receive or transmit information data by wireless.

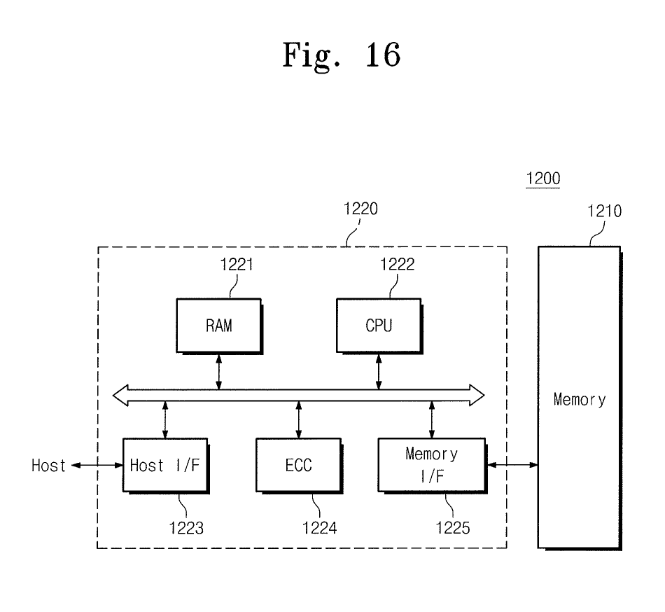

FIG. 16 is schematic block diagram illustrating an example of memory cards including non-volatile memory devices according to exemplary embodiments of the inventive concept.

Referring to FIG. 16, a memory card 1200 for storing mass data may include, for example, a memory device 1210. The memory device 1210 may include at least one of the non-volatile memory devices according to exemplary embodiments mentioned above. Additionally, the memory device 1210 may further include another type of semiconductor memory device which is different from the semiconductor devices according to exemplary embodiments described above. For example, the memory device 1210 may further include a non-volatile memory device (e.g. a magnetic memory device, a phase change memory device, etc), a dynamic random access memory (DRAM) device and/or a static random access memory (SRAM) device. The memory card 1200 may include, for example, a memory controller 1220 that controls data communication between a host and the memory device 1210.

The memory controller 1220 may include, for example, a central processing unit (CPU) 1222 that controls overall operations of the memory card 1200. In addition, the memory controller 1220 may include, for example, an SRAM device 1221 used as an operation memory of the CPU 1222. Moreover, the memory controller 1220 may further include, for example, a host interface unit 1223 and a memory interface unit (Memory I/F) 1225. The host interface unit (Host I/F) 1223 may be configured to include a data communication protocol between the memory card 1200 and the host. The memory interface unit (Memory I/F) 1225 may connect the memory controller 1220 to the memory device 1210. The memory controller 1220 may further include, for example, an error check and correction (ECC) block 1224. The ECC block 1224 may check and correct errors of data which are read out from the memory device 1210. Even though not shown in the drawings, the memory card 1200 may further include, for example, a read only memory (ROM) device that stores code data to interface with the host. The memory card 1200 may be used as, for example, a portable data storage card. Alternatively, the memory card 1200 may realized as, for example, solid state disks (SSD) which are used as hard disks of computer systems.

According to exemplary embodiments of the inventive concept, the uppermost portion of the active region may be disposed at a lower level than the lowermost portion of the gate pattern, and the intensity of the electric field in the uppermost portion of the active region may be greater than the intensity of the electric field in another portion of the active region. The uppermost portion of the active region corresponds to the center area of the top surface of the active region. Thus, charges may be stored in the charge storing pattern disposed on the center area of the top surface of the active region, and it is possible to minimize the amount of charges stored in the charge storing pattern disposed on the edge area of the top surface of the active region. As a result, it is possible to minimize the phenomenon that the charges stored in the charge storing pattern on one active region are spread into the charge storing pattern on a neighboring active region. Thus, a non-volatile memory device with increased reliability may be realized.

Having described exemplary embodiments of the inventive concept, it is further noted that it is readily apparent to those of reasonable skill in the art that various modifications may be made without departing from the spirit and scope of the invention which is defined by the metes and bounds of the appended claims.

1. A non-volatile memory device comprising:
a plurality of device isolation patterns disposed in a substrate to define an active region extending in a first direction;
a gate pattern disposed on the substrate to extend in a second direction crossing the first direction;
a charge storing pattern disposed between the active region and the gate pattern;
a blocking dielectric layer disposed between the charge storing pattern and the gate pattern; and
a tunnel dielectric layer disposed between the active region and the charge storing pattern,
wherein a center area of a top surface of the active region includes one of a rounded surface or a tip, and
wherein the center area of the top surface of the active region corresponds to an uppermost portion of the active region and the uppermost portion of the active region is disposed at a level lower than a lowermost portion of the gate pattern.

2. The non-volatile memory device of claim 1, wherein the lowermost portion of the gate pattern is disposed at a level higher than an uppermost portion of the charge storing pattern.

3. The non-volatile memory device of claim 1, wherein the entire top surface of the active region is rounded.

4. The non-volatile memory device of claim 3, wherein the top surface of the active region has a first radius in a direction parallel to a top surface of the substrate and a second radius in a direction vertical to the top surface of the substrate, and
wherein the first radius is equal to or greater than the second radius.

5. The non-volatile memory device of claim 3, wherein the top surface of the active region has a first radius in a direction parallel to a top surface of the substrate and a second radius in a direction vertical to the top surface of the substrate, and
wherein the first radius is less than the second radius.

6. The non-volatile memory device of claim 1, wherein the top surface of the active region further includes a first surface connecting the center area of the top surface of the active region to a sidewall of the active region; and
wherein an angle between the sidewall and the first surface is equal to or greater than about 90 degrees and less than about 180 degrees.

7. The non-volatile memory device of claim 6, wherein the entire center area of the top surface of the active region is rounded, and
wherein the rounded center area of the top surface has a radius curvature less than a half of a width of the active region in the second direction.

8. The non-volatile memory device of claim 6, wherein a connection surface of the sidewall and the first surface is rounded, and
wherein the rounded connection surface has a radius curvature less than a half of a width of the active region in the second direction.

9. The non-volatile memory device of claim 6, wherein the center area of the top surface of the active region further includes a second surface parallel to a top surface of the substrate and a connection surface connecting the first surface to the second surface,
wherein the connection surface of the first and second surfaces is rounded, and
wherein the rounded connection surface has a radius curvature less than a half of a width of the active region in the second direction.

10. The non-volatile memory device of claim 1, wherein the tip of the top surface of the active region has a radius curvature less than about 30 percent of a width of the active region in the second direction.

11. The non-volatile memory device of claim 1, wherein the top surface of the active region includes a pair of first surfaces extending in parallel to a top surface of the substrate from a pair of sidewalls of the active region toward the center area of the top surface of the active region,
wherein the center area of the top surface of the active region protrudes above the pair of first surfaces and is rounded, and
wherein a maximum width in the second direction of the center area of the top surface of the active region is less than a minimum width between the pair of sidewalls of the active region.

12. The non-volatile memory device of claim 1, wherein a top surface of the device isolation pattern is disposed at a level lower than the uppermost portion of the active region.

13. The non-volatile memory device of claim 1, wherein a top surface of the device isolation pattern is disposed at a level equal to or higher than the uppermost portion of the active region.

14. The non-volatile memory device of claim 1, wherein the device isolation pattern includes a first dielectric pattern and a second dielectric pattern, and
wherein the first dielectric pattern and the second dielectric pattern includes dielectric materials different from each other, respectively.

15. The non-volatile memory device of claim 1, further comprising:
an air gap disposed in the device isolation pattern,
wherein a top end of the air gap is disposed at a level lower than the uppermost portion of the active region, and
wherein the tunnel dielectric layer, the charge storing pattern and the blocking dielectric layer extend on the device isolation pattern and the air gap.

16. The non-volatile memory device of claim 15, wherein the air gap is in a closed state by the device isolation pattern or the tunnel dielectric layer.

17. The non-volatile memory device of claim 15, wherein a vertical distance from a top surface of the device isolation pattern to the top end of the air gap becomes greater toward the active region.

18. A non-volatile memory device comprising:
a plurality of device isolation patterns disposed in a substrate to define an active region extending in a first direction;
a gate pattern disposed on the substrate to extend in a second direction crossing the first direction;
a charge storing pattern disposed between the active region and the gate pattern;
a blocking dielectric layer disposed between the charge storing pattern and the gate pattern; and
a tunnel dielectric layer disposed between the active region and the charge storing pattern,
wherein a center area of a top surface of the active region corresponds to an uppermost portion of the active region, and
wherein the center area of the top surface of the active region includes an electric field focusing region and a portion of the active region disposed under the electric field focusing region, wherein the lowermost portion of the gate pattern is disposed at a level higher than the electric field focusing region of the active region, and wherein an uppermost portion of the charge storing pattern is disposed at a level lower than the lowermost portion of the gate pattern.

19. The non-volatile memory device of claim 18, wherein an edge area of the top surface of the active region is inclined,
wherein the edge area connects the center area of the top surface of the active region to a sidewall of the active region and
wherein an angle between the edge area and the sidewall is equal to or greater than about 90 degrees and less than about 180 degrees.

20. (canceled)
